(19) United States
(12) Patent Application Publication
(10) Pub. No.: US 2025/0294812 A1
(43) Pub. Date: Sep. 18, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Ken-Ichi GOTO, Hsin-Chu (TW); Gerben DOORNBOS, Kessel-Lo (BE); Georgios VELLIANITIS, Heverlee (BE); Viraj MADHIWALA, Kessel-Lo (BE); Sheng-Chih LAI, Hsinchu (TW)

(21) Appl. No.: 18/612,815

(22) Filed: Mar. 21, 2024

(30) Foreign Application Priority Data
Mar. 13, 2024 (GR) 20240100186

(51) Int. Cl. H01L 29/786; H01L 29/66

(52) U.S. Cl. CPC H10D 30/6755; H10D 99/00

(57) ABSTRACT

A transistor structure may be formed in an interconnect layer (e.g., a backend region) of a semiconductor device. The transistor structure is formed such that an interfacial layer is included between a gate dielectric layer and an oxide-semiconductor channel layer of the transistor structure. The interfacial layer provides a substrate on which the oxide-semiconductor channel layer may be formed to have a particular crystal lattice structure to achieve greater charge carrier mobility in the oxide-semiconductor channel layer than without the interfacial layer. Additionally and/or alternatively, the interfacial layer may prevent or reduce the likelihood of contamination from oxygen (O₂) and/or hydrogen (H₂) from the gate dielectric layer and other layers surrounding the transistor structure.

### CROSS-REFERENCE TO RELATED APPLICATION

This Patent Application claims priority to Greek patent application Ser. No. 20/240,100186, filed on Mar. 13, 2024, and entitled “SEMICONDUCTOR DEVICE AND METHODS OF FORMATION.” The disclosure of the prior Application is considered part of and is incorporated by reference into this Patent Application.

### BACKGROUND

In some cases, a transistor may be formed in an interconnect layer of a semiconductor device. The interconnect layer is sometimes referred to as a backend region or back end of line (BEOL) region of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2C is a diagram of an example implementation of a transistor structure described herein.

FIGS. 3A-3F are diagrams of an example implementation of forming a semiconductor device described herein.

FIGS. 4A-4I are diagrams of an example implementation of forming a transistor structure described herein.

FIG. 5 is a diagram of an example implementation of a transistor structure described herein.

FIGS. 6A and 6B are diagrams of example implementations of a transistor structure described herein.

FIG. 7 is a flowchart of an example process associated with forming a transistor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Forming a transistor in an interconnect layer of a semiconductor device often involves the use of different materials and/or structures than those used in transistors formed in a device layer (e.g., a front end of line (FEOL) region) of the semiconductor device. The transistors in the device layer can be formed in a semiconductor substrate of the semiconductor device, whereas transistors formed in the interconnect layer of the semiconductor device are typically formed in a dielectric layer in the semiconductor device. Thus, oxide-semiconductor materials are often used in the channel layers of the transistors in the interconnect layer because oxide-semiconductor materials offer better integration with the dielectric materials used in the interconnect layer compared to semiconductor materials used in the channel layers of the transistors in the device layer. In particular, oxide-semiconductor materials may be processed at lower temperatures, may achieve greater nucleation uniformity on dielectric materials, and/or may achieve higher crystallinity on dielectric materials than semiconductor materials such as silicon (Si).

However, some types of oxide-semiconductor materials may still suffer from similar challenges as those described above for semiconductor materials when used in a transistor in an interconnect layer of a semiconductor device. For example, p-type oxide-semiconductor materials such as tin oxide (SnO) may be used for a channel layer of a p-type transistor, and such p-type oxide-semiconductor materials may suffer from low crystallinity when deposited on dielectric materials such as silicon oxide (SiOₓ). This may result in low charge carrier mobility in the channel layer, which degrades the performance (e.g., reduces the switching speed and/or reduces channel control) of the p-type transistor.

Additionally and/or alternatively, tin oxide may be susceptible to oxygen (O₂) and/or hydrogen (H₂) contamination from other layers and/or structures in the interconnect layer, resulting in degraded performance and/or failure of the p-type transistor. For example, oxygen contamination may result in formation of tin dioxide (SnO₂), which is an n-type material. This may cause threshold voltage shifting and/or current leakage for the p-type transistor. As another example, hydrogen contamination may result in formation of oxygen vacancies in the channel layers of the p-type transistors, which may increase the density of charge carrier donor states in the channel layers, resulting in increased current leakage in the channel layers.

In some implementations described herein, a transistor structure may be formed in an interconnect layer (e.g., a backend region) of a semiconductor device. The transistor structure is formed such that an interfacial layer is included between a gate dielectric layer and an oxide-semiconductor channel layer of the transistor structure. The interfacial layer provides a substrate on which the oxide-semiconductor channel layer may be formed to have a particular crystal lattice structure to achieve greater charge carrier mobility in the oxide-semiconductor channel layer than without the interfacial layer. Additionally and/or alternatively, the interfacial layer may prevent or reduce the likelihood of contamination from oxygen (O₂) and/or hydrogen (H₂) from the gate dielectric layer and other layers surrounding the transistor structure.

The greater charge carrier mobility in the channel layer may enable faster switching speeds to be achieved for the transistor structure and/or may provide greater channel control for the transistor structure. Moreover, the protection of the oxide-semiconductor channel layer against contamination from oxygen (O₂), provided by the interfacial layer, enables specific properties of the oxide-semiconductor channel layer to be maintained. For example, the interfacial layer protects the oxide-semiconductor from transitioning from a p-type material to an n-type material, which might otherwise occur due to oxygen contamination. Additionally, the protection of the oxide-semiconductor channel layer against contamination from hydrogen (H₂), provided by the interfacial layer, enables a low concentration of oxygen vacancies to be achieved in the oxide-semiconductor channel layer. This may enable a low current leakage to be achieved for the transistor structure.

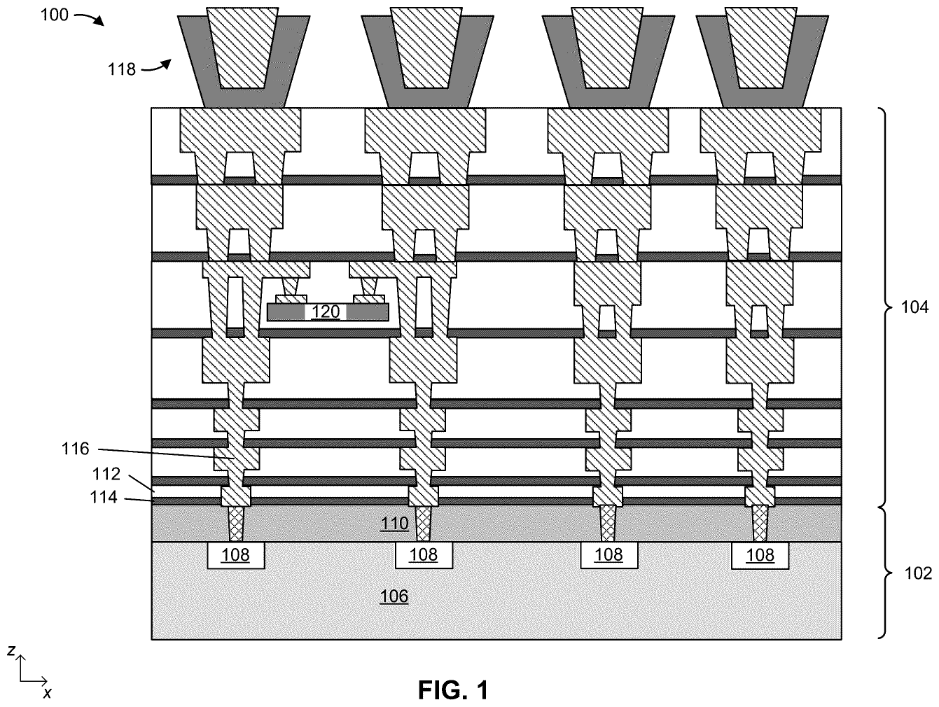

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or FEOL region of the semiconductor device 100. The interconnect layer 104 may also be referred to as a backend region or BEOL region of the semiconductor device 100.

The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Semiconductor devices 108 may be included in and/or on the substrate 106 in the device layer 102 of the semiconductor device 100. The semiconductor devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the semiconductor devices 108 to be selectively etched or protected from etching, and/or to electrically isolate the semiconductor devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the semiconductor devices 108 in the z-direction in the semiconductor device 100. The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 112 and ESLs 114 that are arranged in an alternating manner in the z-direction. The ILD layers 112 and the ESLs 114 may extend in the x-direction and/or in the y-direction in the semiconductor device 100.

The ILD layers 112 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 112 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 114 may each include a silicon nitride (SiₓN_{y}), silicon carbide (SiC), silicon oxynitride (SiON), and/or another suitable dielectric material. In some implementations, an ILD layer 112 and an ESL 114 include different dielectric materials to provide etch selectivity to enable various structures to be formed in the interconnect layer 104.

The interconnect layer 104 includes a plurality of conductive structures 116. One or more of the conductive structures 116 are electrically coupled and/or physically coupled with one or more of the semiconductor devices 108 in the device layer 102. The conductive structures 116 provide electrical routing that enables signals and/or power to be provided to and/or from the semiconductor devices 108. The conductive structures 116 may include a combination of vias, trenches, contacts, plugs, interconnects, metallization layers, conductive traces, and/or other types of conductive structures. The conductive structures 116 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the conductive structures 116 and the ILD layers 112, and/or between the conductive structures 116 and the ESLs 114. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 116 of the interconnect layer 104 may be arranged in in a vertical manner (e.g., in the z-direction). In other words, a plurality of stacked conductive structures 116 extend between the device layer 102 and connection structures 118 above the interconnect layer 104 to facilitate electrical signals and/or power to be routed between the device layer 102 and the connection structures 118. The plurality of stacked conductive structures 116 may be referred to as M-layers. For example, a metal-0 (M0) layer may located at the bottom of the interconnect layer 104 and may be directly coupled with the device layer 102 (e.g., with the contacts or vias of the semiconductor devices 108 in the device layer 102), a metal-1 layer (M1) layer may be located above the M0 layer in the interconnect layer 104, a metal-2 layer (M2) layer may be located above the M1 layer, and so on. Additionally, via layers may be included between vertically arranged M-layers. For example, a via-1 (V1) layer may be included between the M1 layer and the M2 layer to interconnect the M1 layer and the M2 layer, a via-2 (V2) layer may be included between the M2 layer and the M3 layer to interconnect the M2 layer and the M3 layer, and so on.

The connection structures 118 include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. The connection structures 118 enable the semiconductor device 100 to be attached to a semiconductor device package substrate (e.g., an interposer, a redistribution layer (RDL) structure, a printed circuit board (PCB)) and/or to another semiconductor device.

One or more semiconductor devices are also included in the interconnect layer 104 of the semiconductor device 100. For example, a transistor structure 120 is included in an ILD layer 112 of the interconnect layer 104. The transistor structure 120 may be referred to as a backend transistor structure or BEOL transistor structure in that the transistor structure 120 is included in the interconnect layer 104 (e.g., the backend region or BEOL region) of the semiconductor device 100 as opposed to the device layer 102 (e.g., the frontend region or FEOL region) of the semiconductor device 100. The transistor structure 120 is electrically coupled and/or physically coupled with one or more conductive structures 116 in the interconnect layer 104.

As indicated above, FIG. 1 is provided as an example. Other examples may differ from what is described with regard to FIG. 1.

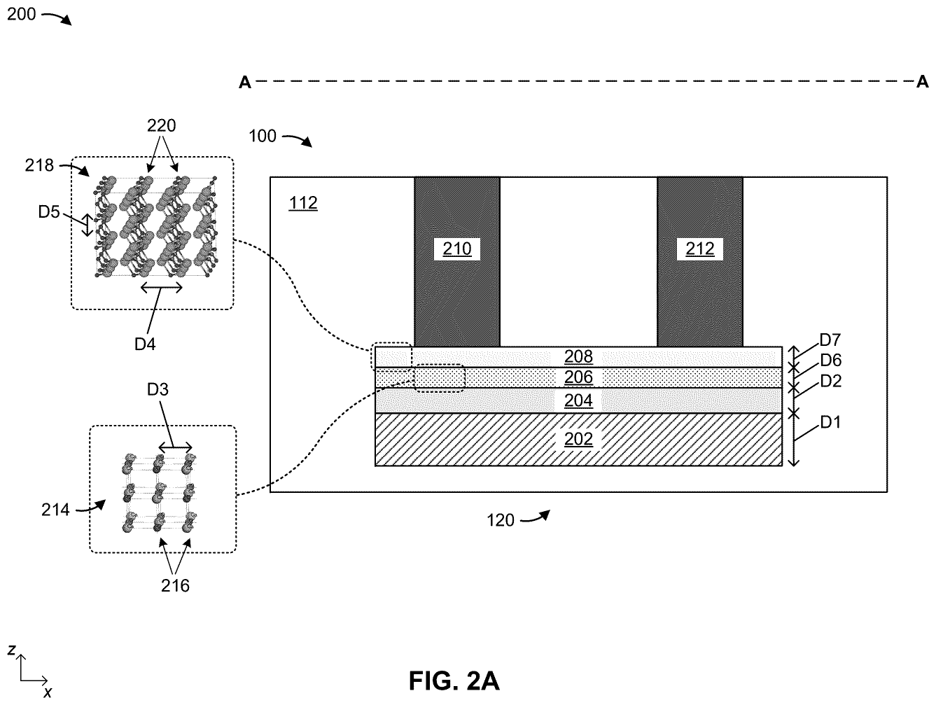

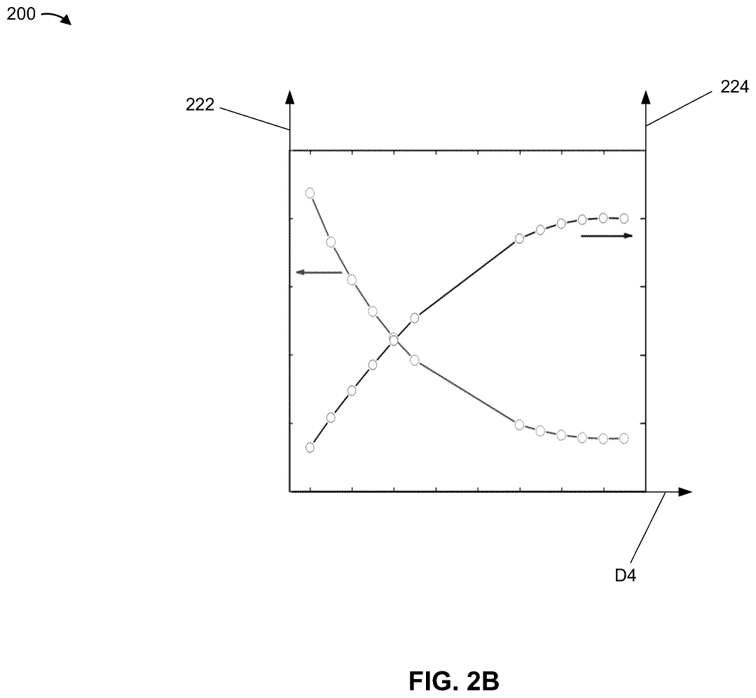

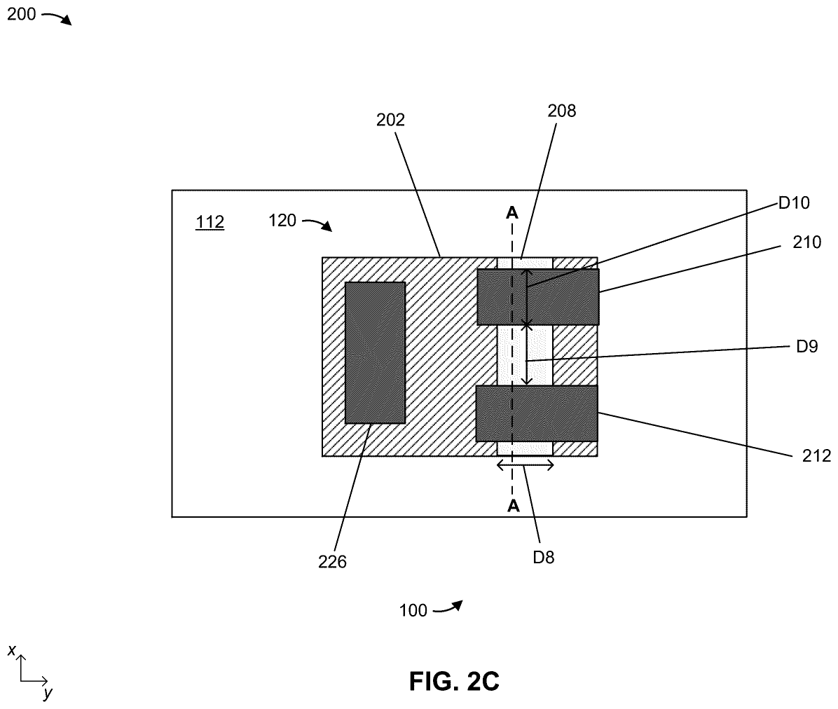

FIGS. 2A-2C is a diagram of an example implementation 200 of a transistor structure 120 described herein. As described in connection with FIG. 1, the transistor structure 120 may be referred to as a backend transistor structure or a BEOL transistor structure that that the transistor structure 120 is included in an ILD layer 112 in the interconnect layer 104 of the semiconductor device 100. The transistor structure 120 may also be referred to as a thin-film transistor (TFT) in that one or more layers (e.g., a gate dielectric layer, a channel layer) of the transistor structure 120 are formed as thin films using thin-film deposition techniques. The transistor structure 120 includes an oxide-semiconductor channel layer, which enables the manufacturing process for the transistor structure 120 to be integrated into the manufacturing process for the interconnect layer 104.

FIG. 2A illustrates a cross-section view of the transistor structure 120. The transistor structure 120 may include a gate electrode 202. The gate electrode 202 may be referred to as a bottom gate electrode or a buried gate electrode in that the gate electrode 202 is located at the bottom of the transistor structure 120. The gate electrode 202 may be electrically coupled with a gate contact, as shown in FIG. 2C. The gate electrode 202 may include one or more electrically conductive metal materials having a relatively low coefficient of thermal expansion (CTE). Examples of such electrically conductive metal-containing materials include platinum (Pt), titanium (Ti), titanium nitride (TiN), tantalum (Ta), tantalum nitride (TaN), tungsten (W), iron (Fe), nickel (Ni), cobalt (Co), chromium (Cr), beryllium (Be), antimony (Sb), iridium (Ir), molybdenum (Mo), osmium (Os), thorium (Th), vanadium (V), palladium (Pd), and/or an alloy thereof, among other examples. In some implementations, a z-direction thickness of the gate electrode 202 (indicated in FIG. 2A as a dimension D1) is included in a range of approximately 5 nanometers to approximately 1000 nanometers. However, other values and/or ranges for the z-direction thickness of the gate electrode 202 are within the scope of the present disclosure.

The transistor structure 120 includes a gate dielectric layer 204. The gate dielectric layer 204 may be included over and/or on the gate electrode 202. The gate dielectric layer 204 may be a high dielectric constant (high-k) gate dielectric layer in that the gate dielectric layer 204 may include one or more high-k dielectric materials that have a dielectric constant greater than the dielectric constant of silicon dioxide (SiO₂-approximately 3.9 dielectric constant). Examples of such high-k dielectric materials include hafnium oxide (HfOₓ such as HfO₂), aluminum oxide (AlₓO_{y} such as Al₂O₃), and/or zirconium oxide (ZrOₓ such as ZrO₂), among other examples. Additionally and/or alternatively, the gate dielectric layer 204 may include a silicon oxide (SiOₓ such as SiO₂) and/or a low dielectric constant (low-k) dielectric layer. The gate dielectric layer 204 may include a thin-film layer having a z-direction thickness (indicated in FIG. 2A as a dimension D2) that is included in a range of approximately 3 nanometers to approximately 100 nanometers. However, other values and/or ranges for the z-direction thickness of the gate dielectric layer 204 are within the scope of the present disclosure.

The transistor structure 120 includes an interfacial layer 206 over and/or on the gate dielectric layer 204, and a p-type oxide-semiconductor channel layer 208 over and/or on the interfacial layer 206. The p-type oxide-semiconductor channel layer 208 includes a p-type oxide-semiconductor material, such as tin oxide (SnO). The electrical conductivity of the p-type oxide-semiconductor channel layer 208 is capable of being selectively controlled by the gate electrode 202 to selectively enable an electrical current to flow between source/drain electrodes 210 and 212 of the transistor structure 120. When a voltage is applied to the gate electrode 202, the p-type oxide-semiconductor channel layer 208 may become electrically conductive, thereby enabling the electrical current to flow between source/drain electrodes 210 and 212. Conversely, when the voltage is removed from the gate electrode 202, the p-type oxide-semiconductor channel layer 208 may become electrically non-conductive, thereby preventing the electrical current from flowing between source/drain electrodes 210 and 212.

The interfacial layer 206 is included between the bottom surface of the p-type oxide-semiconductor channel layer 208 and the top surface of the gate dielectric layer 204 to provide a substrate on which the p-type oxide-semiconductor channel layer 208 is formed to have a particular crystal lattice structure. The interfacial layer 206 is formed of a material that has a crystal lattice structure 214 in which a lattice constant (indicated in FIG. 2A as dimension D3) between adjacent crystal layers 216 promotes formation of a particular crystal lattice structure 218 in the p-type oxide-semiconductor channel layer 208 when the p-type oxide-semiconductor channel layer 208 is formed on the interfacial layer 206. In particular, the lattice constant (dimension D3) between adjacent crystal layers 216 in the crystal lattice structure 214 of the interfacial layer 206 promotes formation a (110) crystal phase in the crystal lattice structure 218 of the p-type oxide-semiconductor channel layer 208.

The interfacial layer 206 promotes growth of the (110) crystal phase in the crystal lattice structure 218 of the p-type oxide-semiconductor channel layer 208 in that the crystal lattice structure 218 of the p-type oxide-semiconductor channel layer 208 approximately conforms to the crystal lattice structure 214 of the interfacial layer 206 when the p-type oxide-semiconductor channel layer 208 is formed on the interfacial layer 206. This results in a larger lattice constant (indicated in FIG. 2A as dimension D4) between horizontally adjacent crystal layers 220 in the crystal lattice structure 218 of the p-type oxide-semiconductor channel layer 208 than if the p-type oxide-semiconductor channel layer 208 were formed directly on the gate dielectric layer 204. The lattice constant (dimension D4) between horizontally adjacent crystal layers 220 in the crystal lattice structure 218 may be greater than the vertical distance (indicated in FIG. 2A as dimension D5) between molecules in the crystal lattice structure 218.

The larger lattice constant (dimension D4) between horizontally adjacent crystal layers 220 in the crystal lattice structure 218 that results from forming the p-type oxide-semiconductor channel layer 208 on the interfacial layer 206 promotes formation of the (110) crystal phase in the crystal lattice structure 218 in that the (110) crystal phase forms at larger grain sizes than other crystal phases such as a (001) crystal phase. The larger lattice constant (dimension D4) between horizontally adjacent crystal layers 220 in the crystal lattice structure 218 enables larger grain sizes to be grown in the crystal lattice structure 218, thereby facilitating formation of the (110) crystal phase in the crystal lattice structure 218 and inhibiting growth of other crystal phases such as the (001) crystal phase.

Accordingly, at least a portion of the crystal lattice structure 218 of the p-type oxide-semiconductor channel layer 208 is composed of the (110) crystal phase. The (110) crystal phase in the material of the p-type oxide-semiconductor channel layer 208 has greater charge carrier mobility (e.g., greater hole mobility) than other crystal phases such as the (001) crystal phase. For example, the (110) crystal phase may have approximately 10 times (10×) greater charge carrier mobility (e.g., greater hole mobility) than the (001) crystal phase. Thus, forming the p-type oxide-semiconductor channel layer 208 on the interfacial layer 206 to facilitate growth of the (110) crystal phase in the p-type oxide-semiconductor channel layer 208 enables a greater charge carrier mobility to be achieved in the p-type oxide-semiconductor channel layer 208 than if the p-type oxide-semiconductor channel layer 208 is formed directly on the gate dielectric layer 204 (which might otherwise result in formation of an amorphous structure in the p-type oxide-semiconductor channel layer 208). In some implementations, the crystal lattice structure 218 of the p-type oxide-semiconductor channel layer 208 is composed of a majority of the (110) crystal phase (e.g., at least 50% of the crystal lattice structure 218 is the (110) crystal phase) to achieve a sufficiently high charge carrier mobility the p-type oxide-semiconductor channel layer 208. In some implementations, the crystal lattice structure 218 of the p-type oxide-semiconductor channel layer 208 is composed of approximately 70% or greater of the (110) crystal phase. In some implementations, the crystal lattice structure 218 of the p-type oxide-semiconductor channel layer 208 is composed of approximately 95% or greater of the (110) crystal phase. In some implementations, the (110) crystal phase is the dominant crystal phase in the crystal lattice structure 218, in that the (110) crystal phase makes up the largest portion of the crystal lattice structure 218 than any other crystal phase. The greater the percentage of the crystal lattice structure 218 that is composed of the (110) crystal phase, the greater the charge carrier mobility that can be achieved in the p-type oxide-semiconductor channel layer 208. In some implementations, the charge carrier mobility that can be achieved in the p-type oxide-semiconductor channel layer 208 is linearly dependent on the percentage of the crystal lattice structure 218 that is composed of the (110) crystal phase.

Moreover, forming the p-type oxide-semiconductor channel layer 208 on the interfacial layer 206 to facilitate growth of the (110) crystal phase in the p-type oxide-semiconductor channel layer 208 results in a larger bandgap for the p-type oxide-semiconductor channel layer 208 than if the p-type oxide-semiconductor channel layer 208 is formed directly on the gate dielectric layer 204, which may enable a lower off current (I_{off}) to be achieved for the transistor structure 120. The lower off current results in less current leakage through the p-type oxide-semiconductor channel layer 208.

In some implementations, the material of the interfacial layer 206 has a lattice constant (dimension D3) that is greater than or approximately equal to the lattice constant (dimension D4) of the (110) crystal phase in the crystal lattice structure 218 of the p-type oxide-semiconductor channel layer 208. This increases the likelihood of formation of the (110) crystal phase in the crystal lattice structure 218 of the p-type oxide-semiconductor channel layer 208, and/or increases the composition of the (110) crystal phase in the crystal lattice structure 218 of the p-type oxide-semiconductor channel layer 208. As an example, if the p-type oxide-semiconductor channel layer 208 includes tin oxide (SnO), the lattice constant (dimension D4) of the (110) crystal phase in the crystal lattice structure 218 of the p-type oxide-semiconductor channel layer 208 may be approximately 4.89 angstroms. Thus, in the example, the material of the interfacial layer 206 has a lattice constant (dimension D3) that is greater than or approximately equal to 4.89 angstroms. Examples of such materials include strontium oxide (SrO), barium oxide (BaO), and/or calcium oxide (CaO) doped with a high concentration of strontium (Sr) (e.g., approximately 40% to approximately 50% strontium by weight).

In some implementations, the material of the interfacial layer 206 has a lattice constant (dimension D3) that is greater than the lattice constant (dimension D4) of the (001) crystal phase in the crystal lattice structure 218 of the p-type oxide-semiconductor channel layer 208, which also promotes formation of the (110) crystal phase in the crystal lattice structure 218 of the p-type oxide-semiconductor channel layer 208. As an example, if the p-type oxide-semiconductor channel layer 208 includes tin oxide (SnO), the lattice constant (dimension D4) of the (001) crystal phase in the crystal lattice structure 218 of the p-type oxide-semiconductor channel layer 208 may be approximately 3.81 angstroms. Thus, in the example, the material of the interfacial layer 206 has a lattice constant (dimension D3) that is greater than 3.81 angstroms. Examples of such materials include magnesium oxide (MgO), calcium oxide (CaO), and/or calcium oxide (CaO) doped with greater than 0% to approximately 50% strontium by weight.

Other examples of materials for the interfacial layer 206 include metal-oxide materials such as yttrium oxide (YₓO_{y} such as Y₂O₃), lithium oxide (LiₓO such as Li₂O), and/or lanthanum oxide (LaₓO_{y} such as La₂O₃), among other examples. In some implementations, the interfacial layer 206 includes an oxide of two or more metals such as calcium (Ca), magnesium (Mg), yttrium (Y), lithium (Li), lanthanum (La), strontium (Sr), and/or barium (Ba), among other examples.

The metal-oxide material of the interfacial layer 206 may also have a sufficiently high bandgap (e.g., greater than approximately 4 electron volts (eV), among other examples) such that the interfacial layer 206 does not contribute (or minimally contributes) to gate leakage in the transistor structure 120. In some implementations, the metal-oxide material of the interfacial layer 206 has a bandgap that is approximately equal to or greater than the bandgap of the gate dielectric layer 204.

In addition to promoting growth of the (110) crystal phase in the p-type oxide-semiconductor channel layer 208, the interfacial layer 206 also blocks, inhibits, and/or resists diffusion of oxygen (O₂) and/or hydrogen (H₂) into the p-type oxide-semiconductor channel layer 208 from layers and/or structures below the p-type oxide-semiconductor channel layer 208. For example, the interfacial layer 206 also blocks, inhibits, and/or resists diffusion of oxygen (O₂) and/or hydrogen (H₂) into the p-type oxide-semiconductor channel layer 208 from the gate electrode 202, the gate dielectric layer 204, and/or the ILD layer 112 below the p-type oxide-semiconductor channel layer 208. The metal-oxide material of the interfacial layer 206 may have a greater change in Gibbs free energy (AG) than a change in Gibbs free energy of the material(s) (e.g., high-k dielectric materials, low-k dielectric materials) of the gate dielectric layer 204. The greater change in Gibbs free energy of the metal-oxide material of the interfacial layer 206 enables the interfacial layer 206 to resist intermixing with the gate dielectric layer 204 and/or with other layers and/or structures such as the gate electrode 202 and the ILD layer 112. This reduces the likelihood of oxygen (O₂) and/or hydrogen (H₂) diffusing from these layers and/or structures through the interfacial layer 206 and into the p-type oxide-semiconductor channel layer 208.

The interfacial layer 206 may be a thin-film layer having a z-direction thickness (indicated in FIG. 2A as a dimension D6) that is included in a range of approximately 3nanometers to approximately 30 nanometers. If the z-direction thickness of the interfacial layer 206 is less than approximately 3 nanometers, the interfacial layer 206 may not sufficiently control the formation of the crystal lattice structure 218 in the p-type oxide-semiconductor channel layer 208 and/or the interfacial layer 206 may not sufficiently block the diffusion of oxygen (O₂) and/or hydrogen (H₂) into the p-type oxide-semiconductor channel layer 208. If the z-direction thickness of the interfacial layer 206 is greater than approximately 30 nanometers, the total oxide thickness between the gate electrode 202 and the p-type oxide-semiconductor channel layer 208 (which may correspond to the thickness of the gate dielectric layer 204 and the thickness of the interfacial layer 206) may result in insufficient control over the electrical conductivity in the p-type oxide-semiconductor channel layer 208. If the z-direction thickness of the interfacial layer 206 is included in the range of approximately 3 nanometers to approximately 30 nanometers, sufficient control over the formation of the crystal lattice structure 218 in the p-type oxide-semiconductor channel layer 208 may be achieved and sufficient blockage of the diffusion of oxygen (O₂) and/or hydrogen (H₂) may be achieved, while enabling sufficient control over the electrical conductivity in the p-type oxide-semiconductor channel layer 208 to be achieved. However, other values for the z-direction thickness of the interfacial layer 206, and ranges other than approximately 3 nanometers to approximately 30 nanometers, are within the scope of the present disclosure. Moreover, the thickness of the interfacial layer 206 may be greater for implementations in which higher gate voltages are used for the transistor structure 120, such as implementations in which the transistor structure 120 is a medium-voltage transistor or a high-voltage transistor.

The p-type oxide-semiconductor channel layer 208 may be a thin-film layer having a z-direction thickness (indicated in FIG. 2A as a dimension D7) that is included in a range of approximately 0.5 nanometers to approximately 30 nanometers. However, other values and/or ranges for the z-direction thickness of the p-type oxide-semiconductor channel layer 208 are within the scope of the present disclosure.

The source/drain electrodes 210 and 212 above and/or on the p-type oxide-semiconductor channel layer 208. The source/drain electrodes 210 and 212 may be in direct physical contact with the p-type oxide-semiconductor channel layer 208, or one or more layers (e.g., liners, barrier layers, adhesion layers) may be included between the p-type oxide-semiconductor channel layer 208 and the source/drain electrodes 210 and 212. A source/drain electrode may refer to a source region or a drain electrode, individually or collectively, dependent upon the context. The source/drain electrodes 210 and 212 may each include one or more electrically conductive materials, such one or more metals and/or one or more metal-containing materials, among other examples. Examples of such materials include aluminum (Al), titanium (Ti), tantalum (Ta), tungsten (W), ruthenium (Ru), cobalt (Co), copper (Cu), gold (Au), platinum (Pt), nickel (Ni), titanium nitride (TiN), and/or indium tin oxide (ITO), among other examples. In some implementations, the z-direction thickness of each of the source/drain electrodes 210 and 212 is greater than approximately 5 nanometers. However, other values and/or ranges for the z-direction thickness of each of the source/drain electrodes 210 and 212 are within the scope of the present disclosure.

The source/drain electrodes 210 and 212 may each be electrically coupled with a

conductive structure 116 in the interconnect layer 104 of the semiconductor device 100. This enables electrical inputs (e.g., voltages, electrical currents) to be applied to the source/drain electrode 210 and/or the source/drain electrode 212, and/or enables the source/drain electrode 210 and/or the source/drain electrode 212 to be electrically grounded.

FIG. 2B illustrates relationships between the lattice constant (dimension D4) of the crystal lattice structure 218 of the p-type oxide-semiconductor channel layer 208 and effective mass 222 and charge carrier mobility 224 in the p-type oxide-semiconductor channel layer 208. As shown in FIG. 2B, as the lattice constant (dimension D4) of the crystal lattice structure 218 increases, the effective mass 222 in the p-type oxide-semiconductor channel layer 208 decreases. As a result, the charge carrier mobility 224 in the p-type oxide-semiconductor channel layer 208 decreases, resulting in reduced current leakage and faster switching speeds in the p-type oxide-semiconductor channel layer 208.

FIG. 2C illustrates a top view of the transistor structure 120 and a location of the cross-section along line A-A in FIG. 2A. As shown in FIG. 2C, the source/drain electrodes 210 and 212 may extend laterally outward past the sides of the p-type oxide-semiconductor channel layer 208 in the y-direction in the semiconductor device 100. Similarly, the gate electrode 202 may extend laterally outward past the sides of the p-type oxide-semiconductor channel layer 208, as well as laterally outward past the source/drain electrodes 210 and 212, in the y-direction in the semiconductor device 100. This enables a gate contact 226 to be formed on the gate electrode 202.

As further shown in FIG. 2C, the transistor structure 120 may have one or more additional dimensions, such as a dimension D8, a dimension D9, and/or a dimension D10, among other examples. The dimension D8 corresponds to a y-direction width of the p-type oxide-semiconductor channel layer 208. In some implementations, the dimension D8 is included in a rage of approximately 5 nanometers to approximately 1000 nanometers. However, other values and/or ranges for the dimension D8 are within the scope of the present disclosure. The dimension D9 corresponds to an x-direction distance between the source/drain electrodes 210 and 212. The dimension D9 may also be referred to as a gate length (L_{g}) of the transistor structure 120. In some implementations, the dimension D9 is included in a rage of approximately 5 nanometers to approximately 1000 nanometers. However, other values and/or ranges for the dimension D9 are within the scope of the present disclosure. The dimension D10 corresponds to an x-direction width of the source/drain electrode 210 and/or of the source/drain electrode 212. In some implementations, the dimension D10 is included in a rage of approximately 5 nanometers to approximately 1000 nanometers. However, other values and/or ranges for the dimension D10 are within the scope of the present disclosure.

As indicated above, FIGS. 2A-2C are provided as examples. Other examples may differ from what is described with regard to FIGS. 2A-2C.

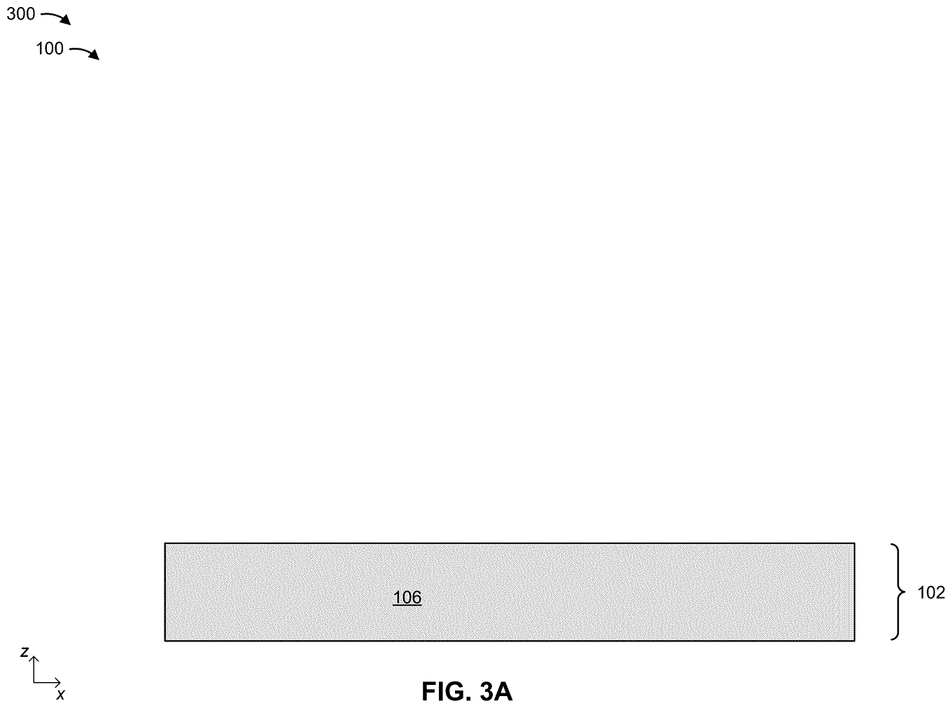

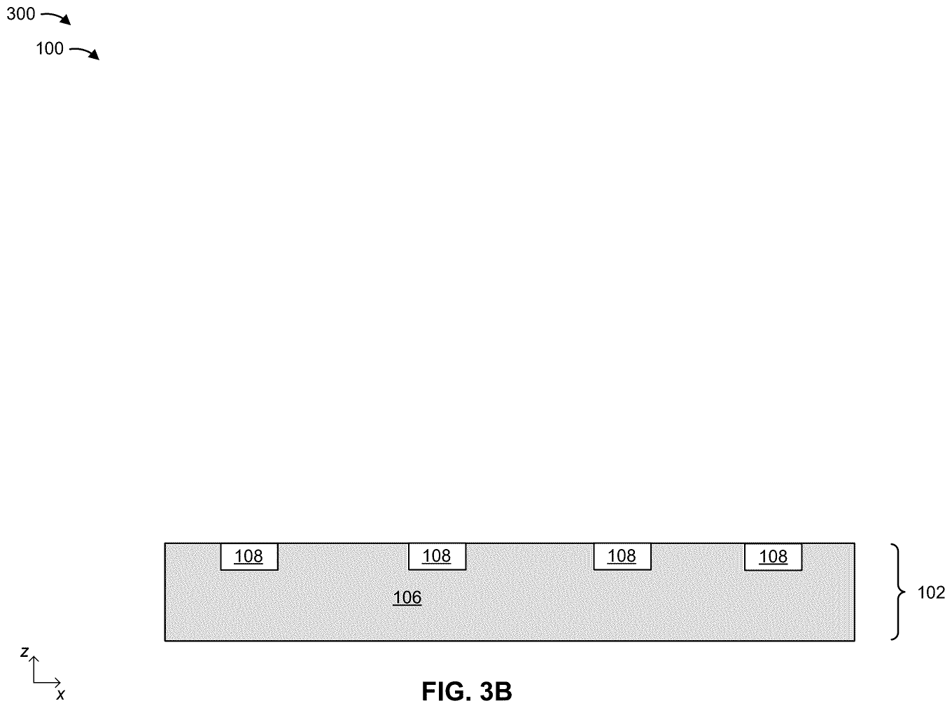

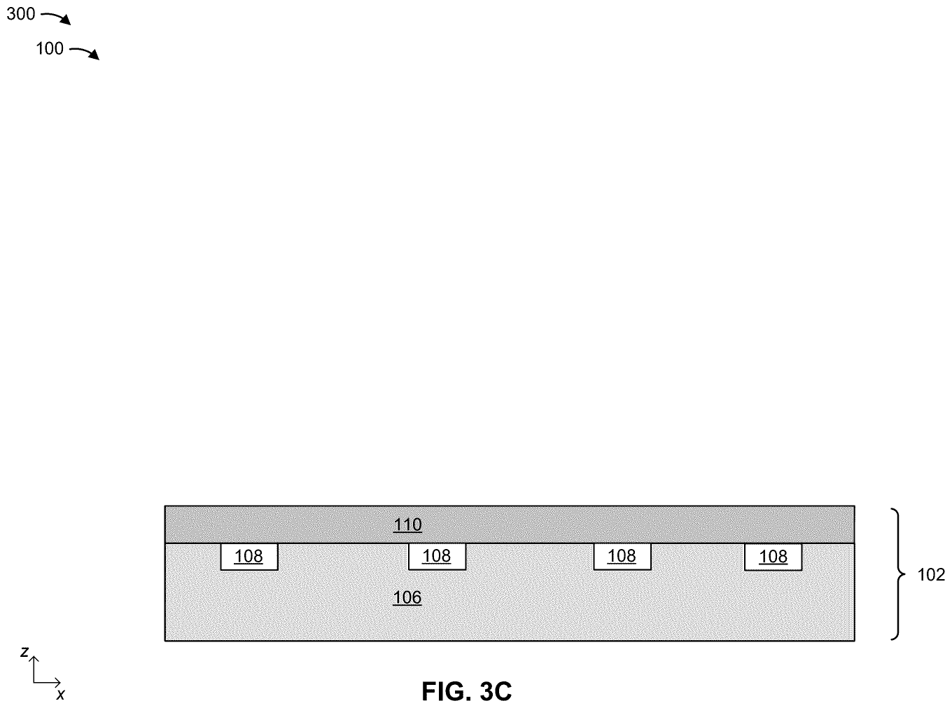

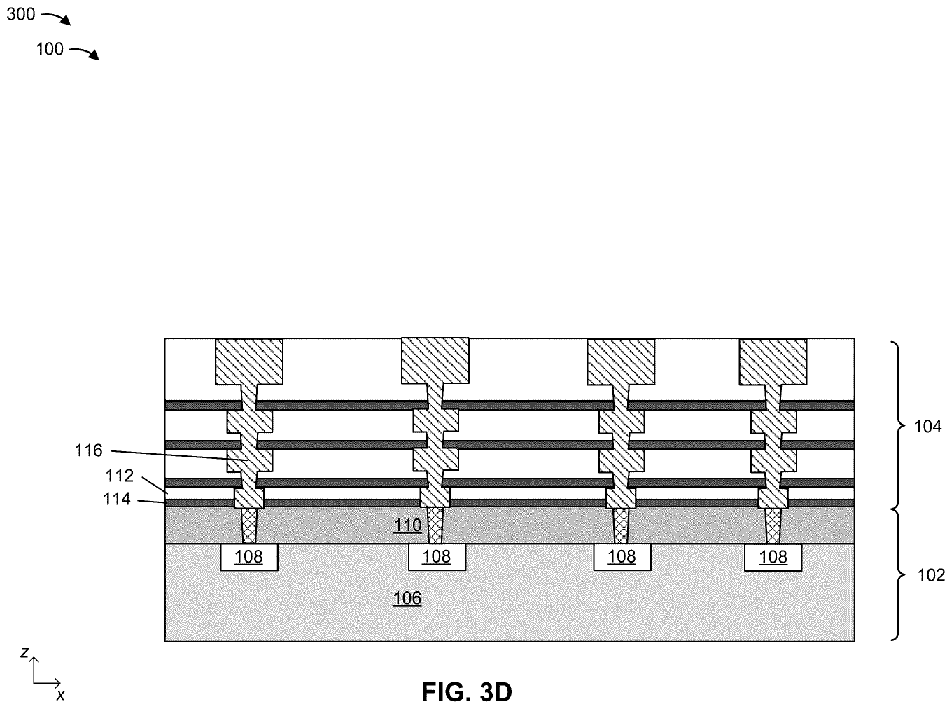

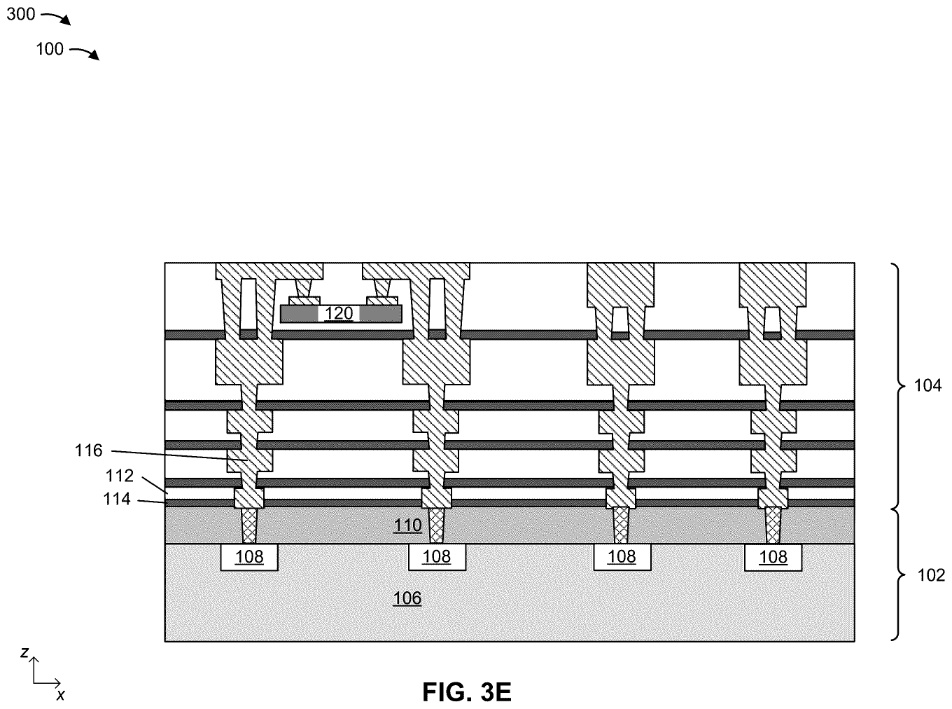

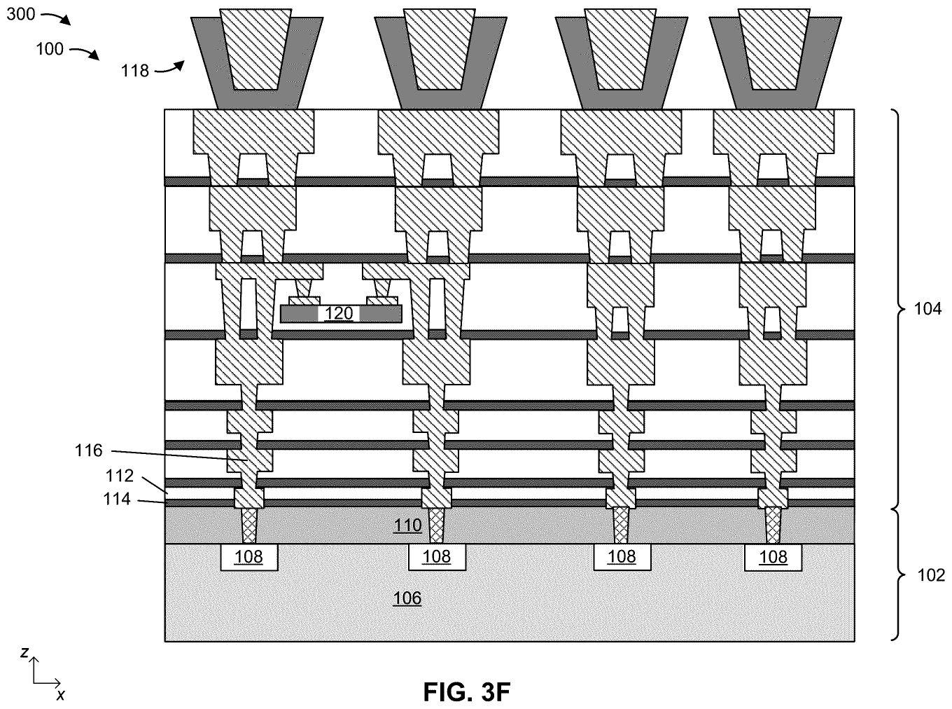

FIGS. 3A-3F are diagrams of an example implementation 300 of forming the semiconductor device 100 described herein. In some implementations, one or more of the semiconductor processing operations described in connection with FIGS. 3A-3F may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 106 is provided. The substrate 106 may be provided in the form of a semiconductor wafer such as a silicon (Si) wafer may be provided as an SOI wafer, and/or another type of semiconductor work piece.

As shown in FIG. 3B, the semiconductor devices 108 (e.g., the frontend semiconductor devices) may be formed in and/or on the substrate 106 in the device layer 102 of the semiconductor device 100. One or more semiconductor processing tools may be used to form one or more portions of the semiconductor devices 108. For example, a deposition tool may be used to perform various deposition operations to deposit layers and/or structures of the semiconductor devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the semiconductor devices 108. As another example, a planarization tool may be used to planarize portions of the semiconductor devices 108. As another example, a plating tool may be used to deposit metal structures and/or layers of the semiconductor devices 108.

As shown in FIG. 3C, a deposition tool is used to deposit the dielectric layer 110 over and/or on the substrate 106 and over and/or on the semiconductor devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to planarize the dielectric layer 110 after the dielectric layer 110 is deposited.

As shown in FIG. 3D, a first portion of the interconnect layer 104 of the semiconductor device 100 is formed above the dielectric layer 110. One or more deposition tools are used to deposit alternating layers of ILD layers 112 and ESLs 114 in the first portion of the interconnect layer 104 of the semiconductor device 100. In this way, the ILD layers 112 and ESLs 114 may be arranged in the z-direction in the semiconductor device 100. One or more deposition tools may be used to deposit each of the ILD layers 112 and each of the ESLs 114 using a PVD technique, an ALD technique, a CVD technique, an oxidation technique, and/or another suitable deposition technique. In some implementations, a planarization tool may be used to planarize the ILD layers 112 and/or the ESLs 114 after the ILD layers 112 and/or the ESLs 114 are deposited.

As further shown in FIG. 3D, a deposition tool, an exposure tool, a developer tool, an etch tool, a planarization tool, and/or a plating tool are used to perform various operations to form the conductive structures 116 in the first portion of the interconnect layer 104 of the semiconductor device 100. The conductive structures 116 may be included in the ILD layers 112 and/or the ESLs 114, and may be electrically coupled with the semiconductor devices 108 in the device layer 102. In some implementations, the ILD layers 112, the ESLs 114, and the conductive structures 116 may built up in the z-direction in metallization layers. For example, a first ESL 114 and a first ILD layer 112 may be formed, recesses may be formed in first ESL 114 and/or in the first ILD layer 112, and first conductive structures 116 (e.g., an MO metallization layer) may be formed in the recesses. A second ESL 114 and a second ILD layer 112 may be formed above the first ESL 114 and the first ILD layer 112, recesses may be formed in second ESL 114 and/or in the second ILD layer 112, and second conductive structures 116 (e.g., an M1 metallization layer) may be formed in the recesses. The remaining metallization layers of the first portion of the interconnect layer 104 may be formed in a similar manner. Additionally, via layers may be formed to interconnect the metallization layers in the interconnect layer 104. The via layers may include conductive structures 116 corresponding to vias or interconnects that interconnect two or more metallization layers in the interconnect layer 104.

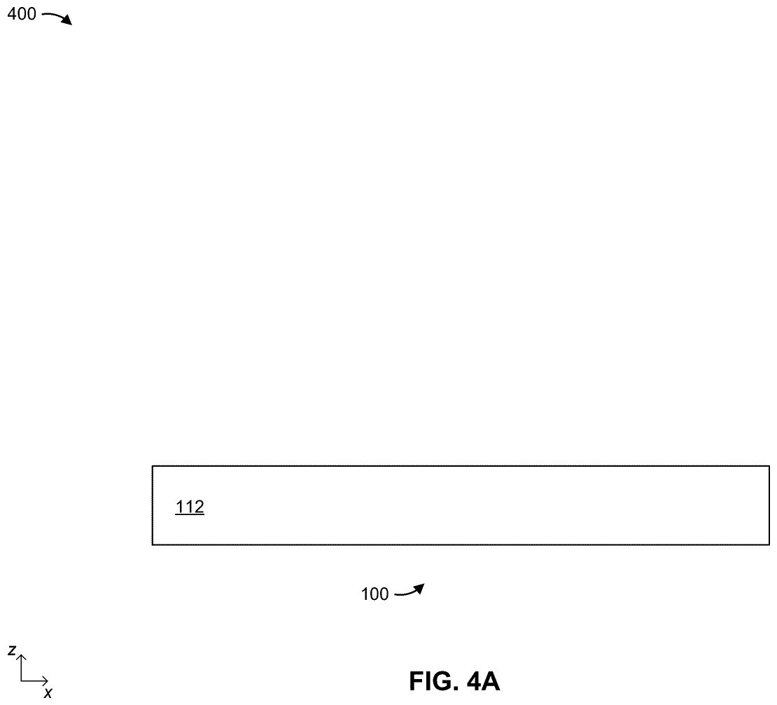

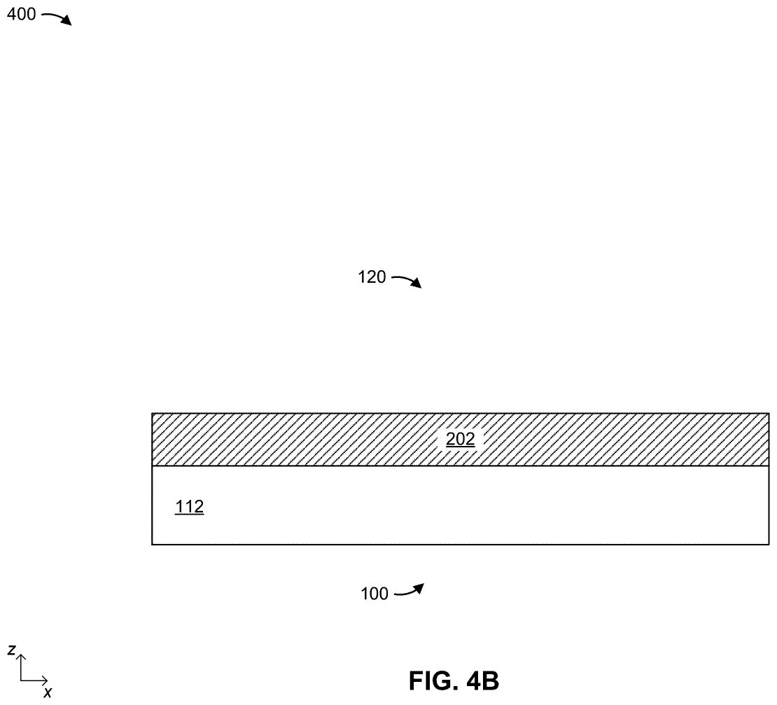

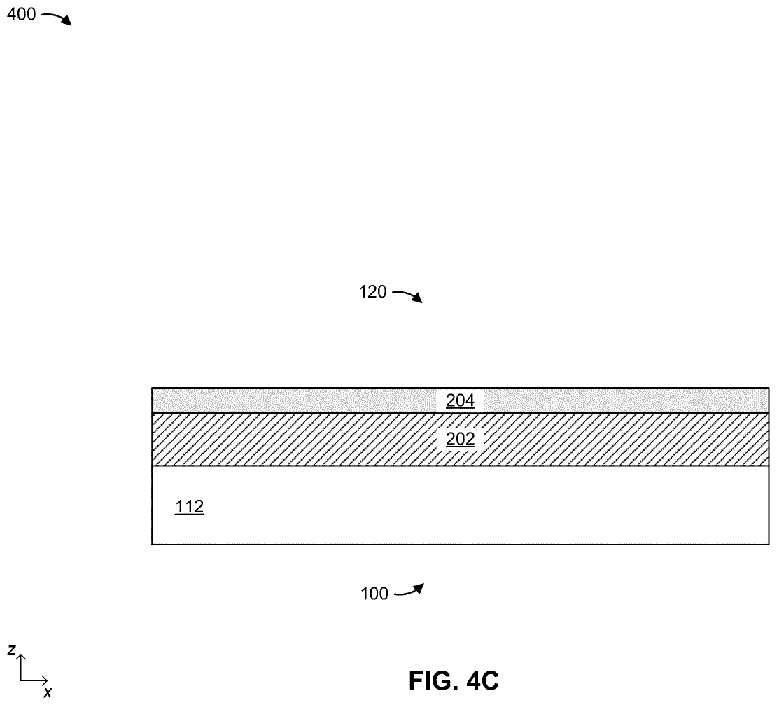

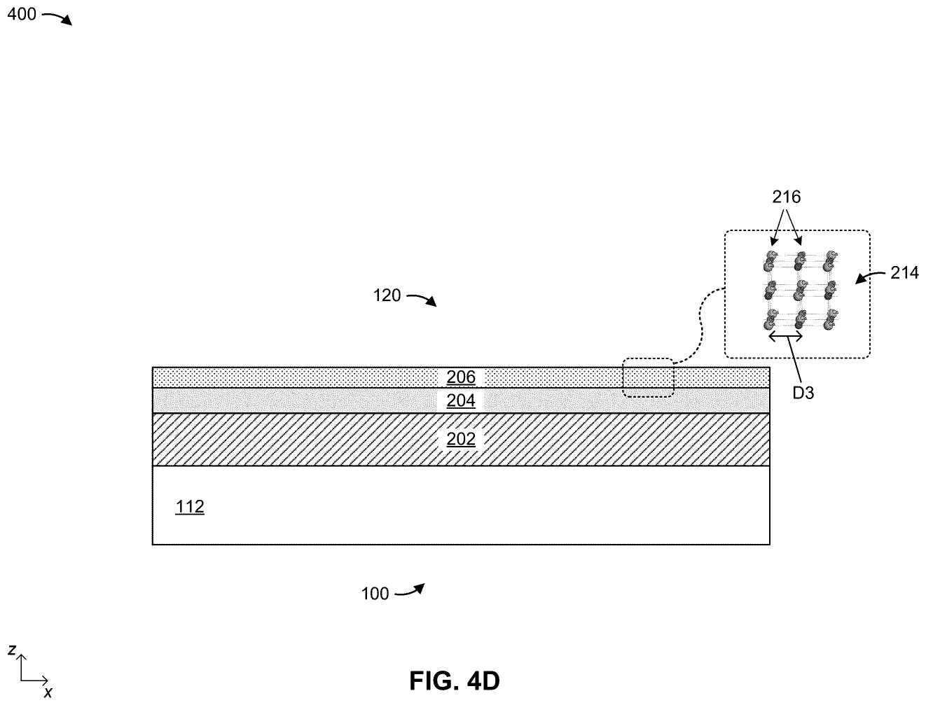

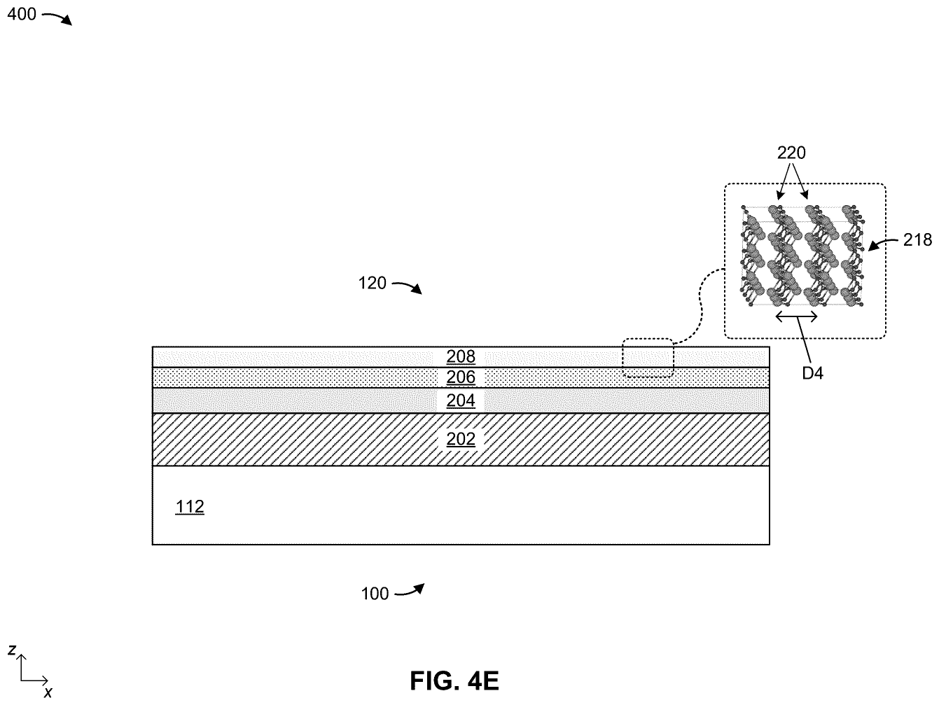

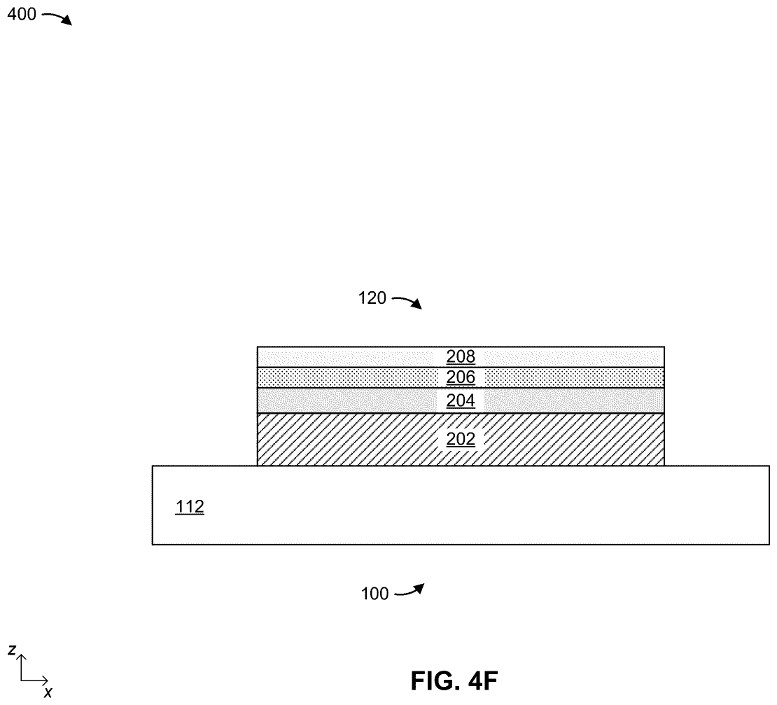

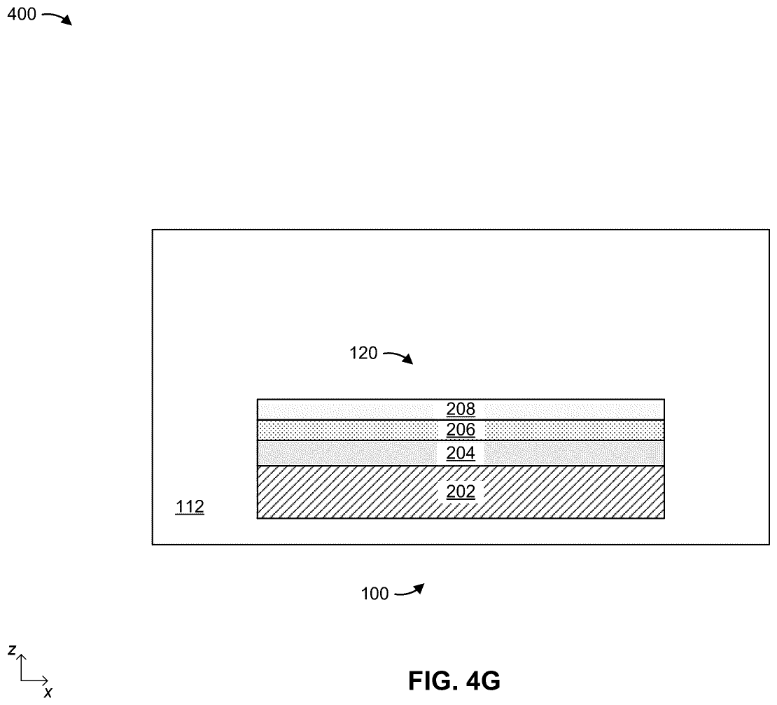

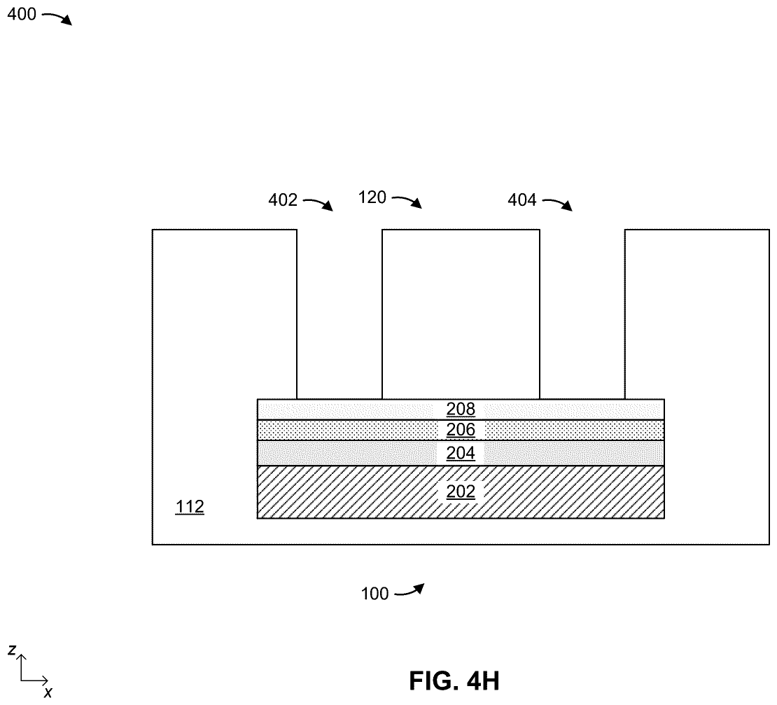

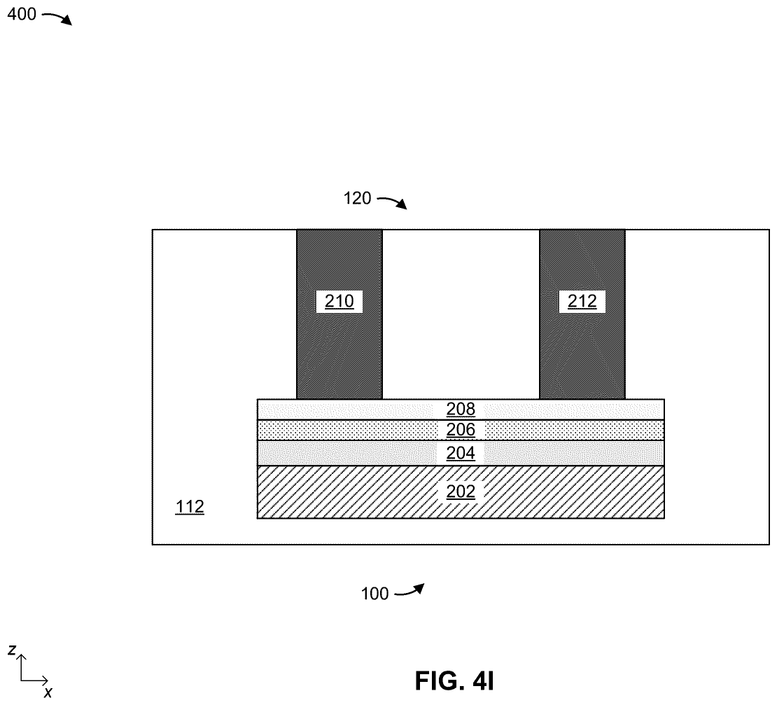

As shown in FIG. 3E, a second portion of the interconnect layer 104 of the semiconductor device 100 is formed over and/or on the first portion of the interconnect layer 104. Techniques similar to those described in connection with FIG. 3D may be performed to form the second portion of the interconnect layer 104. Additionally, a transistor structure 120 (e.g., a backend transistor structure or a BEOL transistor structure) is formed in an ILD layer 112 in the second portion of the interconnect layer 104. Conductive structures 116 may be formed on the transistor structure 120 to electrically connect the transistor structure 120 in the interconnect layer 104. An example implementation of forming the transistor structure 120 is illustrated and described in connection with FIGS. 4A-4I.

As shown in FIG. 3F, a third portion of the interconnect layer 104 may be formed above the second portion of the interconnect layer 104 that includes the transistor structure 120. The third portion of the interconnect layer 104 may be formed using a similar combination of techniques as described in connection with FIGS. 3D and 3E.

As further shown in FIG. 3F, the connection structures 118 are formed on the interconnect layer 104 such that the connection structures 118 are electrically coupled and/or physically coupled with one or more conductive structures 116 in the interconnect layer 104. A deposition tool may be used to deposit the connection structures 118 using a CVD technique, a PVD technique, an ALD technique, an electroplating technique, and/or a deposition technique other than as described above in connection with FIG. 1. In some implementations, a semiconductor packaging tool attaches the connection structures 118 to the semiconductor device 100.

As indicated above, FIGS. 3A-3F are provided as an example. Other examples may differ from what is described with regard to FIGS. 3A-3F.

FIGS. 4A-4I are diagrams of an example implementation 400 of forming the transistor structure 120 described herein. In some implementations, one or more of the semiconductor processing operations described in connection with FIGS. 4A-4I may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool. Turning to FIG. 4A, the operations described in the example implementation 400 may be performed in connection with an ILD layer 112 of the interconnect layer 104 of the semiconductor device 100. The operations described in the example implementation 400 may be performed in connection with forming the semiconductor device 100, as described in connection with FIGS. 3A-3F. For example, the operations described in the example implementation 400 may be performed in connection with forming the interconnect layer 104, as described in connection with FIG. 3E.

As shown in FIGS. 4B the gate electrode 202 may be formed on the ILD layer 112. A deposition tool may deposit the gate electrode 202 using a CVD technique, a PVD technique, an ALD technique, an electroplating technique, and/or a deposition technique other than as described above in connection with FIG. 1. In some implementations, a planarization tool may be used to perform a chemical mechanical planarization (CMP) operation to planarize the gate electrode 202 after the gate electrode 202 is deposited.

As shown in FIG. 4C, the gate dielectric layer 204 may be formed over and/or on the gate electrode 202. A deposition tool may deposit the gate dielectric layer 204 using a CVD technique, a PVD technique, an ALD technique, an oxidation technique, and/or another suitable deposition technique. In some implementations, a planarization tool may be used to perform a CMP operation to planarize the gate dielectric layer 204 after the gate dielectric layer 204 is deposited.

As shown in FIG. 4D, the interfacial layer 206 may be formed over and/or on the gate dielectric layer 204. A deposition tool may be used to deposit the interfacial layer 206 using an ALD technique, a CVD technique, a PVD technique, and/or another suitable deposition technique. In some implementations, a planarization tool is used to perform a CMP operation to planarize the interfacial layer 206 after the interfacial layer 206 is deposited.

The interfacial layer 206 may include a material (e.g., a metal-oxide material) that has a crystal lattice structure 214 having a lattice constant (dimension D3) that satisfies a lattice constant threshold. For example, the interfacial layer 206 may include a material (e.g., a metal-oxide material) that has a crystal lattice structure 214 having a lattice constant (dimension D3) that is approximately equal to or greater than a lattice constant of a particular crystal phase that is to be achieved in the p-type oxide-semiconductor channel layer 208 that is to be formed on the interfacial layer 206. In particular, the interfacial layer 206 may include a material (e.g., a metal-oxide material) that has a crystal lattice structure 214 having a lattice constant (dimension D3) that is approximately equal to or greater than a lattice constant of a (110) crystal phase that is to be achieved in the p-type oxide-semiconductor channel layer 208 that is to be formed on the interfacial layer 206.

As shown in FIG. 4E, the p-type oxide-semiconductor channel layer 208 is formed over and/or on the interfacial layer 206. A deposition tool may be used to deposit the p-type oxide-semiconductor channel layer 208 using an ALD technique, a CVD technique, a PVD technique, and/or another suitable deposition technique. In some implementations, a planarization tool is used to perform a CMP operation to planarize the p-type oxide-semiconductor channel layer 208 after the p-type oxide-semiconductor channel layer 208 is deposited.

Forming the p-type oxide-semiconductor channel layer 208 on the interfacial layer 206 results in a lattice constant (dimension D4) of the crystal lattice structure 218 of the p-type oxide-semiconductor channel layer 208 conforming to the lattice constant (dimension D3) of the crystal lattice structure 214 of the interfacial layer 206. The lattice constant (dimension D4) of the crystal lattice structure 218 of the p-type oxide-semiconductor channel layer 208 conforming to the lattice constant (dimension D3) of the crystal lattice structure 214 of the interfacial layer 206 promotes growth of a (110) crystal phase in the crystal lattice structure 218 of the p-type oxide-semiconductor channel layer 208.

As shown in FIG. 4F the layer stack including the gate electrode 202, the gate dielectric layer 204, the interfacial layer 206, and the p-type oxide-semiconductor channel layer 208, may be etched to define the transistor structure 120. In some implementations, a pattern in a photoresist layer is used to etch the layer stack to define the transistor structure 120. In these implementations, a deposition tool may be used to form the photoresist layer on the p-type oxide-semiconductor channel layer 208. An exposure tool may be used to expose the photoresist layer to a radiation source to pattern the photoresist layer. A developer tool may be used to develop and remove portions of the photoresist layer to expose the pattern. An etch tool may be used to etch the gate electrode 202, the gate dielectric layer 204, the interfacial layer 206, and the p-type oxide-semiconductor channel layer 208 to define the transistor structure 120 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the layer stack based on a pattern.

As shown in FIG. 4G, additional material of the ILD layer 112 may be formed over and/or on the p-type oxide-semiconductor channel layer 208. Moreover, the additional material of the ILD layer 112 may be formed such that the transistor structure 120 is encapsulated by the ILD layer 112. A deposition tool may be used to deposit the additional material of the ILD layer 112 using an ALD technique, a CVD technique, a PVD technique, an oxidation technique, and/or another suitable deposition technique. In some implementations, a planarization tool is used to perform a CMP operation to planarize the ILD layer 112 after the additional material of the ILD layer 112 is deposited.

As shown in FIG. 4H, recesses 402 and 404 may be formed in and/or through the ILD layer 112 such that portions of the top surface of the p-type oxide-semiconductor channel layer 208 are exposed through the recesses 402 and 404. In some implementations, a pattern in a photoresist layer is used to etch the ILD layer 112 to form the recesses 402 and 404. In these implementations, a deposition tool may be used to form the photoresist layer on the ILD layer 112. An exposure tool may be used to expose the photoresist layer to a radiation source to pattern the photoresist layer. A developer tool may be used to develop and remove portions of the photoresist layer to expose the pattern. An etch tool may be used to etch the ILD layer 112 based on the pattern to form the recesses 402 and 404 in the ILD layer 112. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 112 based on a pattern.

As shown in FIG. 4I, the source/drain electrodes 210 and 212 are respectively formed in the recesses 402 and 404. The source/drain electrodes 210 and 212 may land on the portions of the p-type oxide-semiconductor channel layer 208 that are exposed in the recesses 402 and 404 such that the source/drain electrodes 210 and 212 are electrically coupled and/or physically coupled with the p-type oxide-semiconductor channel layer 208.

A deposition tool may be used to deposit the source/drain electrodes 210 and 212 using a CVD technique, a PVD technique, an ALD technique, an electroplating technique, and/or another suitable deposition technique. In some implementations, a planarization tool may be used to planarize the top surfaces of the source/drain electrodes 210 and 212 after the source/drain electrodes 210 and 212 are deposited. The planarization of the source/drain electrodes 210 and 212 results in the top surfaces of the source/drain electrodes 210 and 212 and the top surface of the ILD layer 112 being substantially co-planar.

As indicated above, FIGS. 4A-4I are provided as an example. Other examples may differ from what is described with regard to FIGS. 4A-4I.

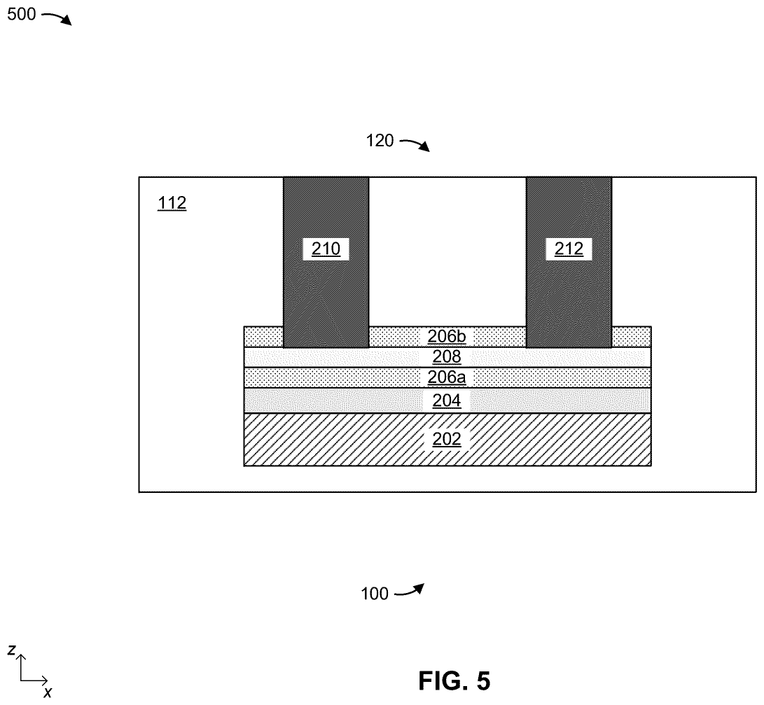

FIG. 5 is a diagram of an example implementation 500 of a transistor structure 120 described herein. As shown in FIG. 5, the example implementation 500 of the transistor structure 120 is similar to the example implementation 200 of the transistor structure 120 illustrated and described in connection with FIGS. 2A-2C. However, in the example implementation 500 of the transistor structure 120 in FIG. 5, the p-type oxide-semiconductor channel layer 208 of the transistor structure 120 is included between a plurality of interfacial layers 206a and 206b. In particular, the p-type oxide-semiconductor channel layer 208 is included on the interfacial layer 206a, and the interfacial layer 206b is included on the p-type oxide-semiconductor channel layer 208.

The interfacial layer 206a is included between the bottom surface of the p-type oxide-semiconductor channel layer 208 and the top surface of the gate dielectric layer 204. Thus, the interfacial layer 206a is included between the p-type oxide-semiconductor channel layer 208 and the gate electrode 202. The interfacial layer 206a provides a substrate on which the p-type oxide-semiconductor channel layer 208 is formed to have a particular crystal lattice structure. In particular, the interfacial layer 206a provides a substrate on which the p-type oxide-semiconductor channel layer 208 is formed such that at least a portion of the crystal lattice structure 218 of the p-type oxide-semiconductor channel layer 208 is composed of a (110) crystal phase. The interfacial layer 206a also blocks, inhibits, and/or resists diffusion of oxygen (O₂) and/or hydrogen (H₂) into the p-type oxide-semiconductor channel layer 208 from layers and/or structures below the p-type oxide-semiconductor channel layer 208 (e.g., the gate electrode 202, the gate dielectric layer 204).

The interfacial layer 206b is included between the top surface of the p-type oxide-semiconductor channel layer 208 and the ILD layer 112. The interfacial layer 206b blocks, inhibits, and/or resists diffusion of oxygen (O₂) and/or hydrogen (H₂) into the p-type oxide-semiconductor channel layer 208 from layers and/or structures above the p-type oxide-semiconductor channel layer 208 (e.g., the ILD layer 112). Thus, the combination of the interfacial layers 206a and 206b protect the p-type oxide-semiconductor channel layer 208 from diffusion of oxygen (O₂) and/or hydrogen (H₂) from multiple directions and/or locations in the semiconductor device 100. In some implementations, the interfacial layer 206a promotes formation of the (110) crystal phase at and/or near the bottom of the p-type oxide-semiconductor channel layer 208, and the interfacial layer 206b promotes formation of the (110) crystal phase at and/or near the top of the p-type oxide-semiconductor channel layer 208. In this way, including both interfacial layers 206a and 206b may further increase the (110) crystal phase composition in the crystal lattice structure 218 of the p-type oxide-semiconductor channel layer 208. For example, the (110) crystal phase may compose approximately 75% of the crystal lattice structure 218 of the p-type oxide-semiconductor channel layer 208 after forming the p-type oxide-semiconductor channel layer 208 on the interfacial layer 206a, and the (110) crystal phase may compose approximately 95% of the crystal lattice structure 218 of the p-type oxide-semiconductor channel layer 208 after forming the interfacial layer 206a on the p-type oxide-semiconductor channel layer 208. However, other values are within the scope of the present disclosure.

In some implementations, the interfacial layers 206a and 206b include the same material and/or the same material combinations. In some implementations, the interfacial layers 206a and 206b include different materials and/or different material combination. In some implementations, the interfacial layers 206a and 206b include the same dopant materials and/or the approximately the same dopant concentrations. In some implementations, the interfacial layers 206a and 206b include different dopant materials and/or different dopant concentrations. In some implementations, the interfacial layers 206a and 206b are formed to approximately a same z-direction thickness. In some implementations, the interfacial layers 206a and 206b are formed to different z-direction thicknesses.

The interfacial layer 206a may be formed on the gate dielectric layer 204 after formation of the gate dielectric layer 204 (described in connection with FIG. 4C) and prior to formation of the p-type oxide-semiconductor channel layer 208 described in connection with FIG. 4E). The interfacial layer 206a may be formed in a similar manner as described in connection with FIG. 4E. The interfacial layer 206b may be formed on the p-type oxide-semiconductor channel layer 208 after formation of the p-type oxide-semiconductor channel layer 208 (described in connection with FIG. 4E) and prior to formation of the additional material of the ILD layer 112 (described in connection with FIG. 4G). The interfacial layer 206b may be formed in a similar manner as described in connection with FIG. 4E.

The source/drain electrodes 210 and 212 may be formed through the interfacial layer 206b such that the source/drain electrodes 210 and 212 land on the p-type oxide-semiconductor channel layer 208 and are in physical contact with the p-type oxide-semiconductor channel layer 208. The recesses 402 and 404 may be formed (described in connection with FIG. 4H) through the interfacial layer 206b to expose the p-type oxide-semiconductor channel layer 208. Thus, the interfacial layer 206b may surround the bottom portions of the source/drain electrodes 210 and 212, and may be in physical contact with the bottom portions of the source/drain electrodes 210 and 212, because of the source/drain electrodes 210 and 212 being formed in the recesses 402 and 404 (described in connection with FIG. 41) that extend through the interfacial layer 206b.

As indicated above, FIG. 5 is provided as an example. Other examples may differ from what is described with regard to FIG. 5.

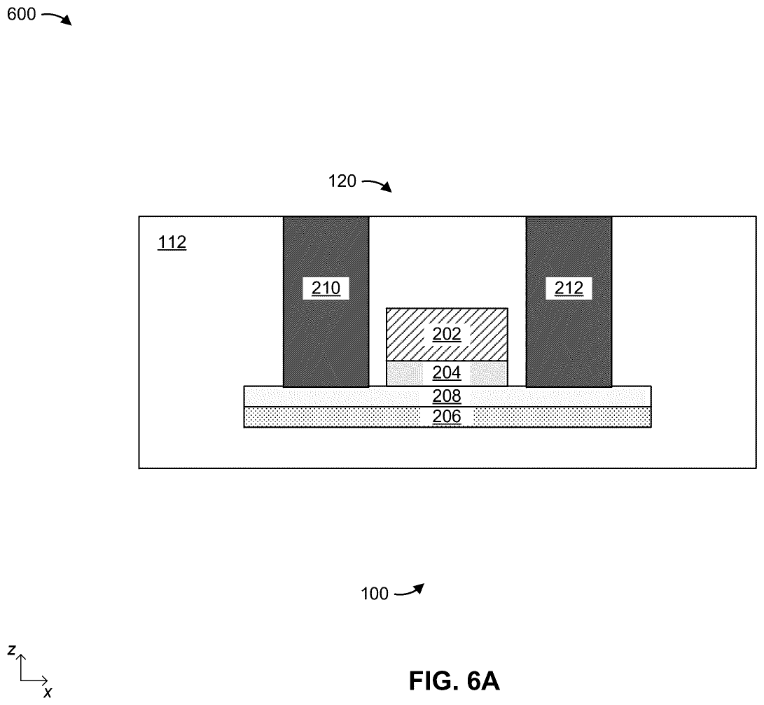

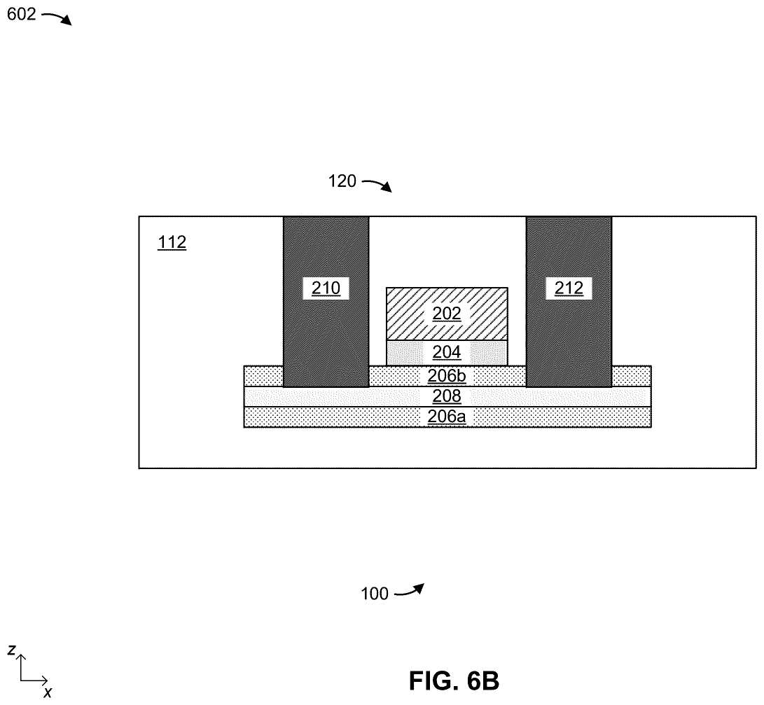

FIGS. 6A and 6B are diagrams of example implementations of a transistor structure 120 described herein. FIG. 6A illustrates an example implementation 600 of the transistor structure 120, and FIG. 6B illustrates an example implementation 602 of the transistor structure 120.

As shown in FIG. 6A, the example implementation 600 of the transistor structure 120 is similar to the example implementation 200 of the transistor structure 120 illustrated and described in connection with FIG. 2A. For example, the example implementation 600 of the transistor structure 120 includes the p-type oxide-semiconductor channel layer 208 on the interfacial layer 206. However, the transistor structure 120 includes a top gate electrode in the example implementation 600 in FIG. 6A, as opposed to the bottom gate electrode in the example implementation 200 in FIG. 2A. Thus, in the example implementation 600 in FIG. 6A, the gate dielectric layer 204 and the gate electrode 202 are included above the p-type oxide-semiconductor channel layer 208, as opposed to below the p-type oxide-semiconductor channel layer 208 in the example implementation 500 in FIG. 5. The gate electrode 202 and the gate dielectric layer 204 are included between the source/drain electrodes 210 and 212. The gate dielectric layer 204 is included between the gate electrode 202 and the p-type oxide-semiconductor channel layer 208.

The interfacial layer 206 is included between the bottom surface of the p-type oxide-semiconductor channel layer 208 and the ILD layer 112. The interfacial layer 206 provides a substrate on which the p-type oxide-semiconductor channel layer 208 is formed to have a particular crystal lattice structure. In particular, the interfacial layer 206 provides a substrate on which the p-type oxide-semiconductor channel layer 208 is formed such that at least a portion of the crystal lattice structure 218 of the p-type oxide-semiconductor channel layer 208 is composed of a (110) crystal phase. The interfacial layer 206 also blocks, inhibits, and/or resists diffusion of oxygen (O₂) and/or hydrogen (H₂) into the p-type oxide-semiconductor channel layer 208 from layers and/or structures below the p-type oxide-semiconductor channel layer 208 (e.g., the ILD layer 112). The interfacial layer 206 may be formed prior to formation of the gate electrode 202, and prior to formation of the gate dielectric layer 204. The interfacial layer 206 is also formed prior to formation of the p-type oxide-semiconductor channel layer 208 (described in connection with FIG. 4E). The interfacial layer 206 may be formed in a similar manner as described in connection with FIG. 4D, except that the interfacial layer 206 in the example implementation 600 of the transistor structure 120 is formed on the ILD layer 112, as opposed to being formed on the gate dielectric layer 204.

The gate dielectric layer 204 may be formed in a similar manner as described in connection with FIG. 4D, except that the gate dielectric layer 204 is formed on the p-type oxide-semiconductor channel layer 208 in the example implementation 600 of the transistor structure 120, as opposed to being formed on the gate electrode 202. The gate electrode 202 is formed in a manner as described in connection with FIG. 4B, except that the gate electrode 202 is formed on the gate dielectric layer 204 in the example implementation 600 of the transistor structure 120, as opposed to being formed in a recess 402 in the ILD layer 112.

The source/drain electrodes 210 and 212 may be formed such that the source/drain electrodes 210 and 212 land on the p-type oxide-semiconductor channel layer 208 and are in physical contact with the p-type oxide-semiconductor channel layer 208. The recesses 402 and 404, and the source/drain electrodes 210 and 212 respectively formed in the recesses 402 and 404, may be formed on opposing sides of the gate electrode 202.

As shown in FIG. 6B, the example implementation 602 of the transistor structure 120 is similar to the example implementation 500 of the transistor structure 120 illustrated and described in connection with FIG. 5. For example, the example implementation 602 of the transistor structure 120 includes the p-type oxide-semiconductor channel layer 208 on the interfacial layer 206a, and the interfacial layer 206b on the p-type oxide-semiconductor channel layer 208.

However, the transistor structure 120 includes a top gate electrode in the example implementation 602 in FIG. 6B, as opposed to the bottom gate electrode in the example implementation 500 in FIG. 5. Thus, in the example implementation 602 in FIG. 6B, the gate dielectric layer 204 and the gate electrode 202 are included above the p-type oxide-semiconductor channel layer 208, as opposed to below the p-type oxide-semiconductor channel layer 208 in the example implementation 500 in FIG. 5. The gate electrode 202 and the gate dielectric layer 204 are included between the source/drain electrodes 210 and 212. The gate dielectric layer 204 is included between the gate electrode 202 and the interfacial layer 206b (e.g., the interfacial layer that is on top of the p-type oxide-semiconductor channel layer 208), as opposed to being between the gate electrode 202 and the interfacial layer 206a (e.g., the interfacial layer that is under the p-type oxide-semiconductor channel layer 208).

The interfacial layer 206a is included between the bottom surface of the p-type oxide-semiconductor channel layer 208 and the ILD layer 112. The interfacial layer 206a provides a substrate on which the p-type oxide-semiconductor channel layer 208 is formed to have a particular crystal lattice structure. In particular, the interfacial layer 206a provides a substrate on which the p-type oxide-semiconductor channel layer 208 is formed such that at least a portion of the crystal lattice structure 218 of the p-type oxide-semiconductor channel layer 208 is composed of a (110) crystal phase. The interfacial layer 206a also blocks, inhibits, and/or resists diffusion of oxygen (O₂) and/or hydrogen (H₂) into the p-type oxide-semiconductor channel layer 208 from layers and/or structures below the p-type oxide-semiconductor channel layer 208 (e.g., the

ILD layer 112). The interfacial layer 206b is included between the top surface of the p-type oxide-semiconductor channel layer 208 and the bottom surface of the gate dielectric layer 204. Thus, the interfacial layer 206a is included between the p-type oxide-semiconductor channel layer 208 and the gate electrode 202. The interfacial layer 206b blocks, inhibits, and/or resists diffusion of oxygen (O₂) and/or hydrogen (H₂) into the p-type oxide-semiconductor channel layer 208 from layers and/or structures above the p-type oxide-semiconductor channel layer 208 (e.g., the gate electrode 202, the gate dielectric layer 204). Thus, the combination of the interfacial layers 206a and 206b protect the p-type oxide-semiconductor channel layer 208 from diffusion of oxygen (O₂) and/or hydrogen (H₂) from multiple directions and/or locations in the semiconductor device 100.

The interfacial layer 206b may be formed on the p-type oxide-semiconductor channel layer 208 after formation of the p-type oxide-semiconductor channel layer 208 (described in connection with FIG. 4E) and prior to formation of the additional material of the ILD layer 112 (described in connection with FIG. 4G). The interfacial layer 206b may be formed in a similar manner as described in connection with FIG. 4D.

The gate dielectric layer 204 may be formed in a similar manner as described in connection with FIG. 4D, except that the gate dielectric layer 204 is formed on the interfacial layer 206b in the example implementation 600 of the transistor structure 120, as opposed to being formed on the gate electrode 202. The gate electrode 202 is formed in a manner as described in connection with FIG. 4B, except that the gate electrode 202 is formed on the gate dielectric layer 204 in the example implementation 600 of the transistor structure 120, as opposed to being formed in a recess 402 in the ILD layer 112.

The source/drain electrodes 210 and 212 may be formed through the interfacial layer 206b such that the source/drain electrodes 210 and 212 land on the p-type oxide-semiconductor channel layer 208 and are in physical contact with the p-type oxide-semiconductor channel layer 208. The recesses 402 and 404 may be formed (described in connection with FIG. 4H) through the interfacial layer 206b to expose the p-type oxide-semiconductor channel layer 208. Thus, the interfacial layer 206b may surround the bottom portions of the source/drain electrodes 210 and 212, and may be in physical contact with the bottom portions of the source/drain electrodes 210 and 212, because of the source/drain electrodes 210 and 212 being formed in the recesses 402 and 404 (described in connection with FIG. 41) that extend through the interfacial layer 206b. The recesses 402 and 404, and the source/drain electrodes 210 and 212 respectively formed in the recesses 402 and 404, may be formed on opposing sides of the gate electrode 202.

As indicated above, FIGS. 6A and 6B are provided as examples. Other examples may differ from what is described with regard to FIGS. 6A and 6B.

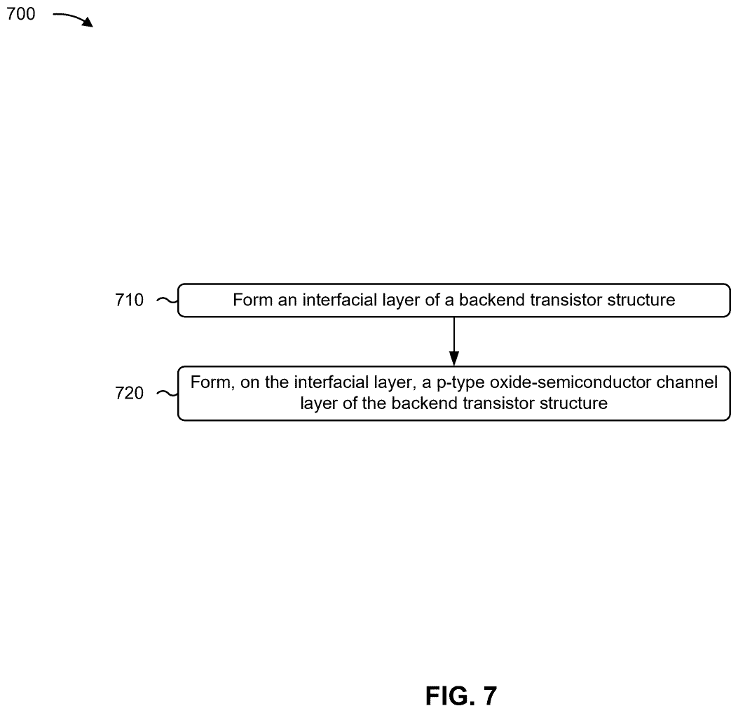

FIG. 7 is a flowchart of an example process 700 associated with forming a transistor structure described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming an interfacial layer of a backend transistor structure (block 710). For example, one or more semiconductor processing tools may be used to form an interfacial layer (e.g., an interfacial layer 206, an interfacial layer 206a) of a backend transistor structure (e.g., a transistor structure 120), as described herein.

As further shown in FIG. 7, process 700 may include forming, on the interfacial layer, a p-type oxide-semiconductor channel layer of the backend transistor structure (block 720). For example, one or more semiconductor processing tools may be used to form, on the interfacial layer, a p-type oxide-semiconductor channel layer (e.g., as p-type oxide-semiconductor channel layer 208) of the backend transistor structure, as described herein. In some implementations, forming the p-type oxide-semiconductor channel layer on the interfacial layer results in a lattice constant (dimension D4) of a crystal lattice structure (e.g., a crystal lattice structure 218) of the p-type oxide-semiconductor channel layer conforming to a lattice constant (dimension D3) of a crystal lattice structure (e.g., a crystal lattice structure 214) of the interfacial layer.

Process 700 may include additional implementations, such as any single implementation or any combination of implementations described below and/or in connection with one or more other processes described elsewhere herein.

In a first implementation, the lattice constant of the crystal lattice structure of the p-type oxide-semiconductor channel layer conforming to the lattice constant of the crystal lattice structure of the interfacial layer promotes growth of a (110) crystal phase in the crystal lattice structure of the p-type oxide-semiconductor channel layer.

In a second implementation, alone or in combination with the first implementation, forming the interfacial layer includes forming the interfacial layer on a high-k gate dielectric layer (e.g., a gate dielectric layer 204) of the backend transistor structure.

In a third implementation, alone or in combination with one or more of the first and second implementations, forming the interfacial layer includes forming the interfacial layer on a backend dielectric layer (e.g., an ILD layer 112) in an interconnect layer (e.g., an interconnect layer 104) of a semiconductor device (e.g., a semiconductor device 100).

In a fourth implementation, alone or in combination with one or more of the first through third implementations, process 700 includes forming another interfacial layer (e.g., an interfacial layer 206, an interfacial layer 206b) on the p-type oxide-semiconductor channel layer.

In a fifth implementation, alone or in combination with one or more of the first through fourth implementations, process 700 includes forming, on the other interfacial layer, a high-k gate dielectric layer (e.g., a gate dielectric layer 204) of the backend transistor structure, and forming, on the high-k gate dielectric layer, a gate electrode (e.g., a gate electrode 202) of the backend transistor structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a transistor structure may be formed in an interconnect layer (e.g., a backend region) of a semiconductor device. The transistor structure is formed such that an interfacial layer is included between a gate dielectric layer and an oxide-semiconductor channel layer of the transistor structure. The interfacial layer provides a substrate on which the oxide-semiconductor channel layer may be formed to have a particular crystal lattice structure to achieve greater charge carrier mobility in the oxide-semiconductor channel layer than without the interfacial layer. Additionally and/or alternatively, the interfacial layer may prevent or reduce the likelihood of contamination from oxygen (O₂) and/or hydrogen (H₂) from the gate dielectric layer and other layers surrounding the transistor structure.

As described in greater detail above, some implementations described herein provide a transistor structure. The transistor structure includes a gate electrode. The transistor structure includes a p-type oxide-semiconductor channel layer, where a majority of a crystal lattice structure of the p-type oxide-semiconductor channel layer is composed of a (110) crystal phase. The transistor structure includes a gate dielectric layer between the gate electrode and the p-type oxide-semiconductor channel layer.

As described in greater detail above, some implementations described herein provide a semiconductor device. The semiconductor device includes an interconnect layer, above a substrate of the semiconductor device, comprising, a plurality of dielectric layers a plurality of conductive structures in the plurality of dielectric layers. The semiconductor device includes a backend transistor structure in a dielectric layer of the plurality of dielectric layers of the interconnect layer, where the backend transistor structure comprises: a gate electrode a p-type oxide-semiconductor channel layer, where at least a portion of a crystal lattice structure of the p-type oxide-semiconductor channel layer is composed of a (110) crystal phase a gate dielectric layer between the gate electrode and the p-type oxide-semiconductor channel layer a first interfacial layer between the gate dielectric layer and the p-type oxide-semiconductor channel layer a second interfacial layer between the dielectric layer of the interconnect layer and the p-type oxide-semiconductor channel layer.

As described in greater detail above, some implementations described herein provide a method. The method includes forming an interfacial layer of a backend transistor structure. The method includes forming, on the interfacial layer, a p-type oxide-semiconductor channel layer of the backend transistor structure, where forming the p-type oxide-semiconductor channel layer on the interfacial layer results in a lattice constant of a crystal lattice structure of the p-type oxide-semiconductor channel layer conforming to a lattice constant of a crystal lattice structure of the interfacial layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor structure, comprising:
a gate electrode;
a p-type oxide-semiconductor channel layer,
wherein a majority of a crystal lattice structure of the p-type oxide-semiconductor channel layer is composed of a (110) crystal phase; and
a gate dielectric layer between the gate electrode and the p-type oxide-semiconductor channel layer.

2. The transistor structure of claim 1, further comprising:
an interfacial layer between the gate dielectric layer and the p-type oxide-semiconductor channel layer,
wherein the interfacial layer comprises a metal-oxide material.

3. The transistor structure of claim 2, wherein the metal-oxide material of the interfacial layer has a greater change in Gibbs free energy than a change in Gibbs free energy of a material of the gate dielectric layer.

4. The transistor structure of claim 2, wherein the metal-oxide material comprises at least one of:
calcium oxide (CaO),
yttrium oxide (YₓO_{y}),
lithium oxide (LiₓO),
lanthanum oxide (LaₓO_{y}),
strontium oxide (SrO),
magnesium oxide (MgO), or
barium oxide (BaO).

5. The transistor structure of claim 2, wherein the metal-oxide material comprises calcium oxide (CaO) doped with strontium (Sr).

6. The transistor structure of claim 2, wherein the gate electrode is below the p-type oxide-semiconductor channel layer in the transistor structure; and
wherein the p-type oxide-semiconductor channel layer is on a top surface of the interfacial layer.

7. The transistor structure of claim 2, wherein the gate electrode is above the p-type oxide-semiconductor channel layer in the transistor structure; and
wherein the interfacial layer is on a top surface of the p-type oxide-semiconductor channel layer.

8. A semiconductor device, comprising:
an interconnect layer, above a substrate of the semiconductor device, comprising:
a plurality of dielectric layers; and
a plurality of conductive structures in the plurality of dielectric layers; and
a backend transistor structure in a dielectric layer of the plurality of dielectric layers of the interconnect layer,
wherein the backend transistor structure comprises:
a gate electrode;
a p-type oxide-semiconductor channel layer,
wherein at least a portion of a crystal lattice structure of the p-type oxide-semiconductor channel layer is composed of a (110) crystal phase;
a gate dielectric layer between the gate electrode and the p-type oxide-semiconductor channel layer;
a first interfacial layer between the gate dielectric layer and the p-type oxide-semiconductor channel layer; and
a second interfacial layer between the dielectric layer of the interconnect layer and the p-type oxide-semiconductor channel layer.

9. The semiconductor device of claim 8, wherein the p-type oxide-semiconductor channel layer is on top of the first interfacial layer; and
wherein the second interfacial layer is on top of the p-type oxide-semiconductor channel layer.

10. The semiconductor device of claim 8, wherein the p-type oxide-semiconductor channel layer is on top of the second interfacial layer; and
wherein the first interfacial layer is on top of the p-type oxide-semiconductor channel layer.

11. The semiconductor device of claim 10, wherein the backend transistor structure further comprises:
a plurality of source/drain electrodes in physical contact with the top of the p-type oxide-semiconductor channel layer,
wherein at least one of the first interfacial layer or the second interfacial layer is in physical contact with the plurality of source/drain electrodes.

12. The semiconductor device of claim 8, wherein a lattice constant of a crystal lattice structure of the first interfacial layer is greater than or approximately equal to a lattice constant of the crystal lattice structure of the p-type oxide-semiconductor channel layer.

13. The semiconductor device of claim 8, wherein the p-type oxide-semiconductor channel layer comprises tin oxide (SnO).

14. The semiconductor device of claim 8, wherein a metal-oxide material of the first interfacial layer comprises an oxide of two or more of:
calcium (Ca),
magnesium (Mg),
yttrium (Y),
lithium (Li),
lanthanum (La),
strontium (Sr), or
barium (Ba).

15. A method, comprising:
forming an interfacial layer of a backend transistor structure; and
forming, on the interfacial layer, a p-type oxide-semiconductor channel layer of the backend transistor structure,
wherein forming the p-type oxide-semiconductor channel layer on the interfacial layer results in a lattice constant of a crystal lattice structure of the p-type oxide-semiconductor channel layer conforming to a lattice constant of a crystal lattice structure of the interfacial layer.

16. The method of claim 15, wherein the lattice constant of the crystal lattice structure of the p-type oxide-semiconductor channel layer conforming to the lattice constant of the crystal lattice structure of the interfacial layer promotes growth of a (110) crystal phase in the crystal lattice structure of the p-type oxide-semiconductor channel layer.

17. The method of claim 15, wherein forming the interfacial layer comprises:
forming the interfacial layer on a high dielectric constant (high-k) gate dielectric layer of the backend transistor structure.

18. The method of claim 15, wherein forming the interfacial layer comprises:
forming the interfacial layer on a backend dielectric layer in an interconnect layer of a semiconductor device.

19. The method of claim 15, further comprising:
forming another interfacial layer on the p-type oxide-semiconductor channel layer.

20. The method of claim 19, further comprising:
forming, on the other interfacial layer, a high dielectric constant (high-k) gate dielectric layer of the backend transistor structure; and
forming, on the high-k gate dielectric layer, a gate electrode of the backend transistor structure.
